(19) United States
(12) Patent Application Publication
(10) Pub. No.: US 2008/0180129 A1
(43) Pub. Date: Jul. 31, 2008

(54) FPGA ARCHITECTURE WITH THRESHOLD VOLTAGE COMPENSATION AND REDUCED LEAKAGE

(75) Inventors: Georges Nabaa, Mountain View, CA (US); Farid Najm, Mississauga (CA); Navid Azizi, Markham (CA)

Correspondence Address: LEWIS AND ROCA, LLP, 1663 Hwy 395, Suite 201, Minden, NV, 89423, US

(73) Assignee: ACTEL CORPORATION

(21) Appl. No.: 11/847,851

(22) Filed: Aug. 30, 2007

Related U.S. Application Data
(60) Provisional application No. 60/824,235, filed on Aug. 31, 2006.

(51) Int. Cl. H03K 19/00; H03K 19/173

(52) U.S. Cl. 326/16; 326/38; 326/39

(57) ABSTRACT

A method for providing transistor threshold voltage compensation in an FPGA integrated circuit with a plurality of programmable circuit blocks includes measuring the effective transistor threshold voltage values of each programmable circuit block and adjusting the effective transistor threshold voltage values of each programmable circuit block to compensate for the difference between the measured effective transistor threshold voltage value and the target effective transistor threshold voltage value.

### REFERENCE TO RELATED APPLICATIONS

This application claims an invention which was disclosed in Provisional Application No. 60/824,235 filed Aug. 31, 2006, entitled “A Novel FPGA Architecture with Threshold Voltage Compensation and Reduced Leakage.” The benefit under 35 USC §119(e) of the United States provisional application is hereby claimed, and the aforementioned provisional application is hereby incorporated herein by reference.

### BACKGROUND OF THE INVENTION

1. Field of the Invention

The invention pertains to the field of integrated circuits. More particularly, the invention pertains to field programmable gate array integrated circuit devices.

2. Description of Related Art

Field Programmable Gate Array (FPGA) integrated circuits are known in the art. An FPGA comprises any number of initially uncommitted logic modules arranged in an array along with an appropriate amount of initially uncommitted routing resources. Logic modules are circuits which can be configured to perform a variety of logic functions like, for example, AND-gates, OR-gates, XOR-gates, inverters, adders, latches, and flip/flops. Routing resources can include a mix of components such as wires, switches, multiplexers, and buffers.

The logic modules and the routing resources have associated control elements (sometimes known as programming bits or configuration bits) which determine the functionality of the logic modules and the interconnectivity of the routing resources. The control elements may be thought of as binary bits having values such as on/off, conductive/non-conductive, true/false, or logic-1/logic-0 depending on the context. The control elements vary according to the technology employed and their mode of data storage may be either volatile or non-volatile. Volatile control elements, such as SRAM bits, lose their programming data when the PLD power supply is disconnected, disabled or turned off. Non-volatile control elements, such as antifuses and floating gate transistors, do not lose their programming data when the PLD power supply is removed. Some control elements, such as antifuses, can be programmed only one time and cannot be erased. Other control elements, such as SRAM bits and floating gate transistors, can have their programming data erased and may be reprogrammed many times. The detailed circuit implementation of the logic modules and routing resources can vary greatly and must be appropriate for the type of control element used.

Typically a user creates a logic design inside manufacturer-supplied design software. The design software then takes the completed design and converts it into the appropriate mix of configured logic modules, maps those logic modules into physical locations inside the FPGA, configures the interconnect to route the signals from one logic module to another, and generates the data structure necessary to assign values to the various control elements inside the FPGA.

Many FPGA architectures employing various different logic modules and interconnect arrangements are known in the art. Some architectures are flat while others are clustered. In a flat architecture, the logic modules may or may not be grouped together with other logic modules, but all of the logic modules have free access to the larger routing architecture. For example, in the AX family of FPGAs offered by Actel Corporation of Mountain View, Calif., the logic modules are grouped together in a repeatable tile containing 12 logic modules (8 are mux-based function generators and 4 are flip/flops) and a variety of routing wires and buffers. The architecture is flat because there is no physical restriction preventing all module inputs and outputs being connected to other parts of the FPGA.

In a clustered architecture, the logic modules are grouped together into clusters which typically have a two level hierarchy of routing resources. The first level typically makes interconnections internal to the cluster while the second level typically allows interconnections between clusters. For example, in the Cyclone FPGA family offered by Altera Corporation of San Jose, Calif., the logic modules are grouped together in a repeatable tile known as a Logic Array Block (LAB) containing 10 logic modules (each with a 4-input look-up table function generator and a flip/flop), a local interconnect group, and row and column interconnect groups—the row and column interconnects providing connectivity between different LABs. This architecture is clustered because at most 26 input signals can enter the cluster while there are a total of 40 logic module inputs. This places a physical restriction on the place and route software since it cannot place sub-circuits with more than 26 inputs into a single LAB. Whether flat or clustered, the core of an FPGA is typically constructed by means of a repeatable tile which can be stepped in rows and columns to form an array.

As is well known in the art, Complementary Metal-Oxide-Semiconductor (CMOS) integrated circuits are typically built using silicon as the base substrate material. CMOS transistors that come in two basic types: N-channel (NMOS) and P-channel (PMOS).

As shown in FIGS. 1A through 1E, NMOS transistors have 4 terminals: a gate terminal, two source/drain terminals, and a body terminal (sometimes known as a bulk terminal or a well terminal). The body is a P-type doped region in which the transistor is located. The source/drain terminals are identically doped N-type regions completely surrounded on the sides and bottom by the P-type body region. The area of the body between the two source/drain regions is completely covered by the gate. This arrangement is shown from a top view in FIG. 1A. The gate is conductive and is isolated from the body and the two source/drain regions by a thin layer of gate oxide. The disposition of the gate oxide is shown from a top view in FIG. 1B.

Since the doping profile is the same for both source/drain terminals, their electrical behavior is symmetrical. By convention for an NMOS transistor, the drain terminal is designated as the source/drain terminal operating at a higher voltage relative to the other source/drain terminal which is designated as the source terminal. Which terminal is the source and which is the drain can change during operation depending on the voltages applied to the various terminals.

When an NMOS transistor is OFF, the two source/drain regions are isolated from each other by the body. As shown in side view in FIG. 1C, the body has P-type doping meaning that impurities are added to the intrinsic silicon in that region such that the dominant electrical carries are holes which carry Positive charge (hence the P in P-type). The source/drain regions have N-type doping meaning that impurities are added to the intrinsic silicon in that region such that the dominant electrical carriers are electrons which carry a Negative charge (hence the N in N-type). Each source/drain diffusion forms a depletion region with the body. A depletion region is an area that is largely devoid of mobile charge carriers.

This arrangement of abutting P-type and N-type regions is known as a P/N junction. As is well known in the art, a P/N junction creates a diode which is a device that conducts substantial current when forward biased and virtually no current when reverse biased. Forward biasing means that the P-type material is at a higher voltage than the N-type material by an amount larger than a critical voltage known as the turn-on voltage, while reverse biasing means just the opposite. Thus with the transistor OFF, virtually no current flows from one source/drain region to another because there is no conduction path between them that does not include a reverse biased diode.

When the voltage on the gate of an NMOS transistor rises, positive charge accumulates on the gate. This positive charge exerts an electric field through the gate oxide which repels the positive carriers intrinsic to the P-type body underneath the gate oxide and attracts negative carriers. If sufficient voltage is supplied, there will be an excess of negative carriers in the body region under the gate. This region acts as though it were N-type material despite its P-type doping. The presence of these excess carriers is called a channel (or N-channel in the case of NMOS devices) as shown in side view in FIG. 1D. When a channel exists, the NMOS device is said to be ON because the channel and the two source/drain regions effectively form a single N-type region making conduction possible (hence the N in the terms N-channel and NMOS). The threshold voltage is exactly the amount of voltage that needs to be applied to the gate relative to the source (i.e., the source/drain region at the lowest voltage level) in order for a channel to first form. Higher voltages on the transistor gate will create a more highly conductive channel and allow a greater amount of current to flow from the drain to the source.

In addition to being ON or OFF, the NMOS transistor can also be biased in a state known as the sub-threshold region as shown in cross section in FIG. 1E. This occurs when the voltage on the gate is insufficiently high to form a channel and insufficiently low that the body region under the gate behaves like P-type material. A depletion region forms under the gate and a small amount of conduction between the source and drain terminals can occur which is sometimes known as sub-threshold leakage current. Typically sub-threshold leakage current is orders of magnitude less than the conduction current when the transistor is ON and orders of magnitude more than the leakage current when the transistor is OFF. The amount of sub-threshold current varies exponentially with the gate voltage, so even a small change in the gate voltage can result a large change in sub-threshold leakage current.

The value of the voltage applied to the body terminal relative to the voltage on the source terminal of the NMOS transistor has an effect on the threshold voltage of the device. This is because changing the voltage on the body terminal modulates the width of the depletion region shown in FIG. 1D. Lowering the body voltage while the transistor is ON with its source and body terminals initially at the same voltage is called negative biasing. Negative biasing widens the depletion region under the channel. This has the effect of weakening the electric field across the gate oxide and reducing the number of negative carriers in the channel. To get a channel of equivalent strength, the voltage on the gate terminal must be increased relative to the source to compensate. This means that the threshold voltage of the NMOS transistor is higher when the body is negatively biased, since a higher gate voltage will be required to form a channel. Raising the voltage on the body terminal above the voltage on the source terminal is called positive biasing and has the opposite effect. It narrows the depletion region, strengthens the electric field across the gate oxide, increases the number of negative carriers in the channel, and reduces the threshold voltage of the NMOS transistor.

As shown in FIGS. 2A through 2E, PMOS transistors also have 4 terminals: a gate terminal, two source/drain terminals, and a body terminal. The primary difference is that the doping type of the diffusions is exactly opposite so that the body is N-type material and the source/drain regions are P-type. This results in a transistor that behaves substantially like the NMOS device except that the polarity of all the voltages is reversed. For example, a negative voltage relative to the source must be applied to the gate in order to create a channel. This puts negative charges on the gate repelling the negative carriers normally occurring in the N-type body and attracting positive carriers. When a channel (or P-channel) exists, the PMOS device is said to be ON because the channel and the two source/drain regions effectively form a single P-type region making conduction possible (hence the P in the terms P-channel and PMOS). Note that in the PMOS case the threshold voltage has a negative value, and that by convention the drain terminal is the source/drain terminal operating at a lower voltage than the other source/drain terminal that is designated the source. Like the NMOS transistor, the PMOS device can be turned ON, turned OFF, operate in the sub-threshold region, and have its threshold voltage controlled by means of the body voltage.

In recent years, semiconductor device geometries have shrunk down into the deep sub-micron region. Shrinking lateral geometries (like, for example, minimum transistor channel width and minimum transistor channel length) have been accompanied by shrinking vertical geometries (like, for example, gate oxide thickness and diffusion depths). Because transistors have become increasingly smaller in all three physical dimensions, the power supply voltages have decreased along with the process geometries to reduce the strength of the electric fields inside the devices in order to prevent destructive breakdowns between the various device terminals. As a result of these trends, a number of process related difficulties have arisen which affect the design of all deep sub-micron integrated circuits, including FPGAs.

CMOS scaling has been driven by the desire for higher transistor densities and faster devices. Historically, innovations for improving performance relied on exploiting ever larger numbers of transistors operating at higher frequencies. Successive technology generations have relied on the parallel reductions in the power supply voltage and the minimum transistor feature size to keep the resulting switching power under control. Unfortunately, controlling the switching power this way comes at the expense of overall circuit performance.

The amount of current that a CMOS transistor can conduct depends on the voltage level that can be applied to the gate of the transistor. While varying somewhat from process to process and foundry to foundry, it typically takes a change in the gate voltage level of approximately 0.6 volts to 0.8 volts from the point where a CMOS transistor is completely OFF to the point where it has just turned ON (i.e., the gate-to-source voltage is exactly the threshold voltage). When the gate voltage is between these two levels, the device is operating in the sub-threshold region and can have significant leakage current.

In order for CMOS logic to operate correctly, it is typically necessary that the power supply voltage be approximately as large as the sum of the typical NMOS threshold voltage plus the absolute value of the typical PMOS voltage. When transistor geometries were above 0.50 micrometers, the power supply voltage was typically 5 volts—well above the approximately 1.6 volts necessary due to the sum of the typical 0.8 volt NMOS threshold voltage and the typical |−0.8| volt PMOS threshold voltage. However, in the latest process generations, for example, the 0.090 micrometer (90 nanometer) or the 0.065 micrometer (65 nanometer) technology nodes, the power supply voltage is typically on the order of 1.00 volt to 1.20 volts. So in deep sub-micron processes, a greatly reduced threshold voltage of approximately 0.4 volts for the NMOS transistors and −0.4 volt for the PMOS transistors is used. This means that during the course of normal CMOS logic switching, when an NMOS transistor is “turned off” by applying 0.00 volts to the gate, the NMOS transistor is really operating in the sub-threshold region and is never truly in the OFF state. Similarly, when a PMOS transistor is “turned off” by applying the positive power supply voltage to the gate, the PMOS transistor is also in the sub-threshold region and is never truly in the OFF state. This result in there being significantly more leakage current in deep sub-micron processes.

Compounding the problem is that while the CMOS transistor threshold voltages have been decreased in the latest generation processes, the statistical variation of threshold voltage due to random process variations has not decreased. Furthermore, the reduction in the minimum feature size has caused significant variations in other transistor characteristics such as minimum transistor gate length. This further aggravates the variations in threshold voltage through short channel effect fluctuations. The increased process variations can have a significant effect on circuit performance, power, and yield.

Compensating for within-die (WID) process variations has been an area of active research in the Application Specific Integrated Circuit (ASIC) design community. One prior art ASIC approach is shown in FIG. 3 for the case of a microprocessor. The technique is described in the article Adaptive Body Bias for Reducing the Impacts of Die to Die and Within-Die Parameter Variations on Microprocessor Frequency and Leakage by James Tschanz, James, Kao, and Siuva Narendra, et al, in IEEE Journal of Solid State Circuits, pages 1396-1402, November, 2002. Every significant block in the microprocessor ASIC is given its own Critical Path Proxy circuit and its own Characterizer circuit. The Proxy circuit is created after its associated block is designed and simulated, so as to duplicate the critical path through that block. After the microprocessor is manufactured, the Characterizer circuit can send clock pulses through the Proxy circuit and compare the delay relative to the length of the microprocessor clock period. In this way it can be determined which blocks are operating fast enough and which are failing because the critical path delay is too long. If the block is failing, a technique known as adaptive body-biasing is used to correct the situation on a block-by-block basis. While highly desirable, this approach can be expensive to implement. The Characterizer circuits in particular require a significant amount of area and one must be present in each and every block to get coverage for within-die variations for the entire integrated circuit.

In order for adaptive body-biasing to be feasible, either a so-called triple well CMOS process (like the cross section view in FIG. 4A) or a silicon-on-insulator (SOI) CMOS process (like the cross section view in FIG. 4B) must be used. For the triple well process, the substrate of the integrated circuit is typically doped to be P-type material and is considered the “third well.” It forms the lowest physical layer and is present everywhere on the integrated circuit. The P-substrate will contain Deep N-well regions formed of N-type material which in turn will contain P-well regions formed of P-type material. The Deep N-well and P-well regions contain the PMOS and NMOS transistors respectively. A P-well region must always be completely surrounded on the sides and bottom by Deep N-well to avoid electrically connecting the P-well region to the P-type substrate.

The SOI case does not require any nesting of wells. The substrate is made of an insulating material that prevents conduction between the P-well and N-well regions, so the N-well and P-well regions are built separately. SOI makes for a simpler design approach than the triple well process because fewer well junction interactions need to be considered, but it is more costly and thus less frequently employed. Because of this simplicity, SOI will not be discussed any further since persons skilled in the art who understand the triple well process will easily be able to adapt that knowledge to SOI.

When using a triple well process, the substrate is typically tied to ground. In an integrated circuit without adaptive body-biasing, the Deep N-well regions are typically tied to the CMOS positive power supply and the P-well regions are typically tied to the CMOS negative power supply (which is typically ground as well). Inside the CMOS logic, nodes that switch typically operate at voltages in the range between the CMOS positive power supply and the CMOS negative power supply. For the PMOS transistors, that means that they either operate with their source terminal connected to the CMOS positive power supply or both the source and drain nodes operate between the CMOS positive and negative power supplies. Similarly NMOS transistors either operate with their source terminal connected to the CMOS negative power supply or both the source and drain nodes operate between the CMOS positive and negative power supplies.

If adaptive body-biasing is used in a CMOS circuit, each Deep N-well region is connected to a bias voltage which is close in voltage level to the CMOS positive power supply. The Deep N-well regions can be connected to the same or to a number of different bias voltages. The operating range for this bias voltage depends upon the diode characteristics of the Deep N-well to P-type source/drain junctions on the low side and the various junction diode breakdown characteristics on the high side, though typically the junction breakdown voltages are large enough to not be a practical issue. On the low side a Deep N-well region should not be biased to a voltage level low enough that the junctions with the PMOS transistor source/drain regions become forward biased and start conducting current. Since the diode turn-on voltage is strongly dependent on temperature, prudent designers typically limit themselves to allowing a forward bias on the order of half of the lowest (i.e., the worst case) diode turn-on voltage.

Similarly, if adaptive body-biasing is used, each P-well region is connected to a bias voltage which is close in voltage level to the CMOS negative power supply. The P-well regions can be connected to the same or to a number of different bias voltages. The operating range for this bias voltage depends upon the diode characteristics of the P-well to N-type source/drain junctions on the high side and the various junction diode breakdown characteristics on the low side. Again the junction breakdown voltages are typically large enough to not be a practical issue. On the high side a P-well region should not be biased to a voltage level high enough that the junctions with the NMOS transistor source/drain regions become forward biased and start conducting current. As in the Deep N-well case, designers typically limit themselves to allowing a forward bias on the order of half of the lowest diode turn-on voltage.

Adaptive body-biasing allows the threshold voltages of the PMOS and NMOS transistors to be controlled by setting the body (or well) voltage level. For example, if a circuit is running too slowly, the wells can be forward biased to voltage levels between the CMOS positive and negative power supplies. This will decrease the absolute value of the PMOS and NMOS transistor threshold voltages causing the circuit to run faster. This is an engineering trade-off since the lower threshold voltages will increase the sub-threshold leakage in the circuits resulting in higher power consumption. Similarly, if a block is operating faster than necessary, the wells can be reverse biased to voltage levels outside of the CMOS positive and negative power supplies. This will increase the absolute values of the transistor threshold voltages causing the circuits to run slower and have less sub-threshold leakage. The well bias voltages can be generated using analog circuits well known in the art such as charge pumps, digital to analog converters, and operational amplifiers.

Previous research in reducing FPGA power has ignored within-die process variations. One attempt utilized a dual threshold process combined with dual CMOS positive power supplies. In the dual threshold process, transistors are designated in the design as either high threshold or low threshold devices. The two types of transistors receive a different doping profile in the region directly under the gate which produces transistors with two different average threshold voltages. The high threshold devices are used in circuits which switch infrequently like, for example, SRAM bit control elements in an SRAM-based FPGA. Since these circuits seldom switch, there is no significant performance penalty and the leakage reduction is substantial. The dual power supply approach hard-wires certain sections in the FPGA to the higher voltage supply and other sections to the lower voltage supply. The sections with the higher power supply voltage run faster, so circuits with critical delays in the user's design can be programmed into them, while circuits with timing slack can be programmed into the slower sections connected to the lower voltage supply. While successfully reducing power, this approach does not address the WID process variations at all.

Another approach used a programmable dual power supply. This allowed blocks to be programmed to connect to either a higher voltage level or lower voltage level power supply depending on the performance needs of the blocks. This produced significant power savings, but again WID variations were ignored.

Xilinx, Inc., of San Jose, Calif., disclosed a method for determining critical paths in an FPGA design and adjusting the thresholds of transistors in the critical path circuits in Published U.S. Patent Application 2003/0053335. This method uses body-biasing to adjust the transistor thresholds, however the basis for adjusting them is done inside the design software either by using simulated performance delays or by user designation. This assumes uniform block performance and completely ignores WID variations. This means that the threshold adjustments are not as accurate as those based on an actual analysis of the true threshold values of the transistors as manufactured on the device. Thus the threshold voltage adjustments must be performed within a smaller range for fear of over-adjusting and causing failures.

In U.S. Pat. No. 6,930,510 Xilinx disclosed another scheme for attempting to optimize the trade-off between leakage and speed. This method is only used for a FPGA device that has pre-defined low speed/low leakage interconnects and separate pre-defined high speed/high leakage interconnects manufactured in the device. During the place and route phase of creating a user design, the design software assigns critical path circuits to the high speed resources and non-critical path circuits to the low leakage resources. The transistor threshold voltages in these resources may be set by doping or body-biasing. Like all the other methods WID variations are ignored.

All these techniques assume that the timing delay estimated by the timing analysis tool in the design software is equal to the post-fabrication delay of the actual physical block. However, research has shown this is not a valid assumption in deep sub-micron CMOS integrated circuits. The increased process variations which translate into threshold voltage variations may have a significant effect on circuit performance, power, and yield by causing 30% disparities in chip frequency and a 20× spread in sub-threshold leakage current.

It is highly desirable to be able to measure threshold variations from block to block and adjust them based on the actual measured value in FPGA integrated circuits. This would eliminate the uniform speed assumption common to the prior art methods allowing higher performance, lower power, and increased yield.

### BRIEF DESCRIPTION OF THE DRAWINGS

The present invention is illustrated by way of example, and not by way of limitation, in the following figures. In cases when the same reference number is used in different figures, it refers to like or related structures or methods.

FIGS. 1A-AE are series of five views of an NMOS transistor of the prior art.

FIGS. 2A-2E are series of five views of a PMOS transistor of the prior art.

FIG. 3 shows an application specific integrated circuit using an adaptive body-biasing scheme of the prior art.

FIGS. 4A and 4B are a series of two views showing cross sections of CMOS processes of the prior art.

FIG. 5A shows an illustrative FPGA architecture suitable for use with the present invention.

FIG. 5B shows the illustrative FPGA architecture of FIG. 5A with additional details.

FIG. 6 shows the illustrative repeatable tile of FIG. 5B with additional details.

FIGS. 7A and 7B is a series of two views of the characterizer circuit of FIG. 5A and FIG. 5B with additional details.

FIG. 8 shows a first embodiment of a method of the present invention.

FIG. 9 shows a second embodiment of a method of the present invention.

FIG. 10 shows a third embodiment of a method of the present invention.

FIG. 11 shows a fourth embodiment of a method of the present invention.

FIG. 12 shows a fifth embodiment of a method of the present invention.

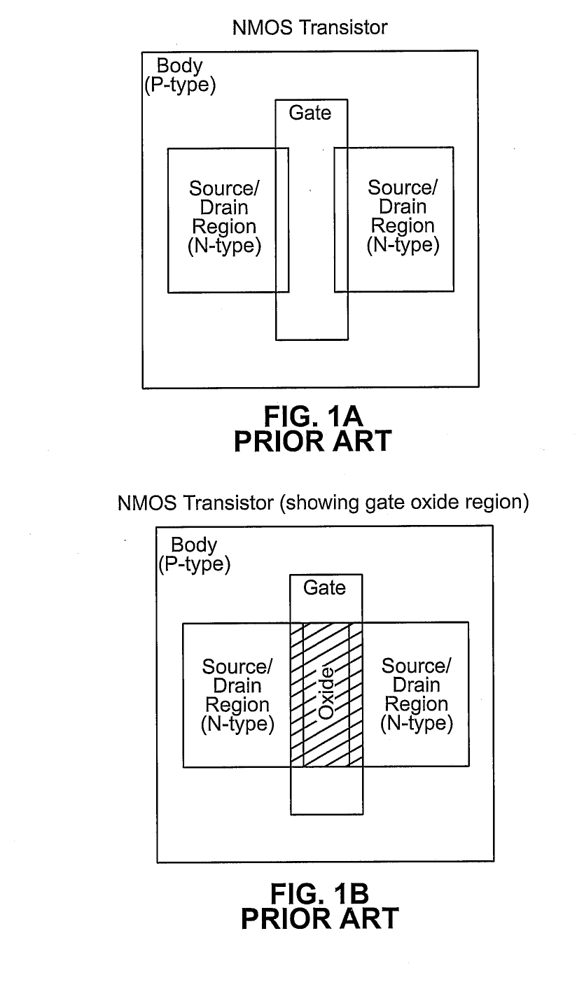

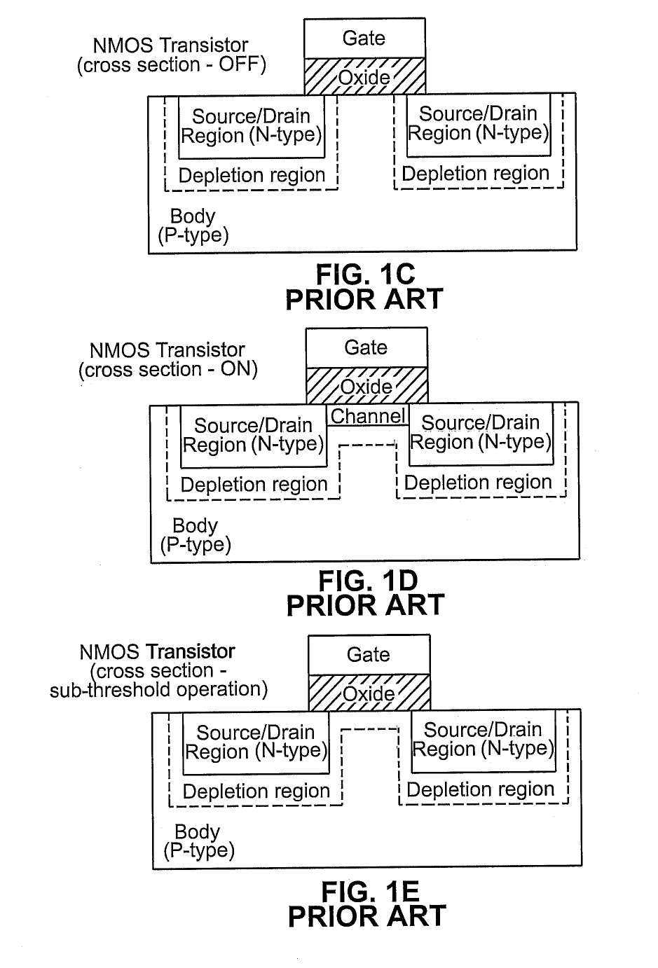

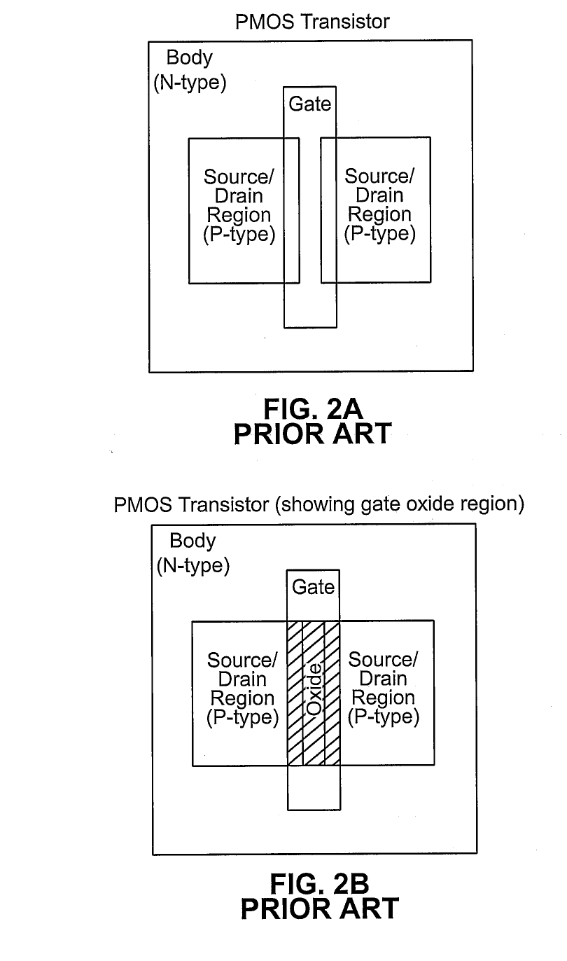

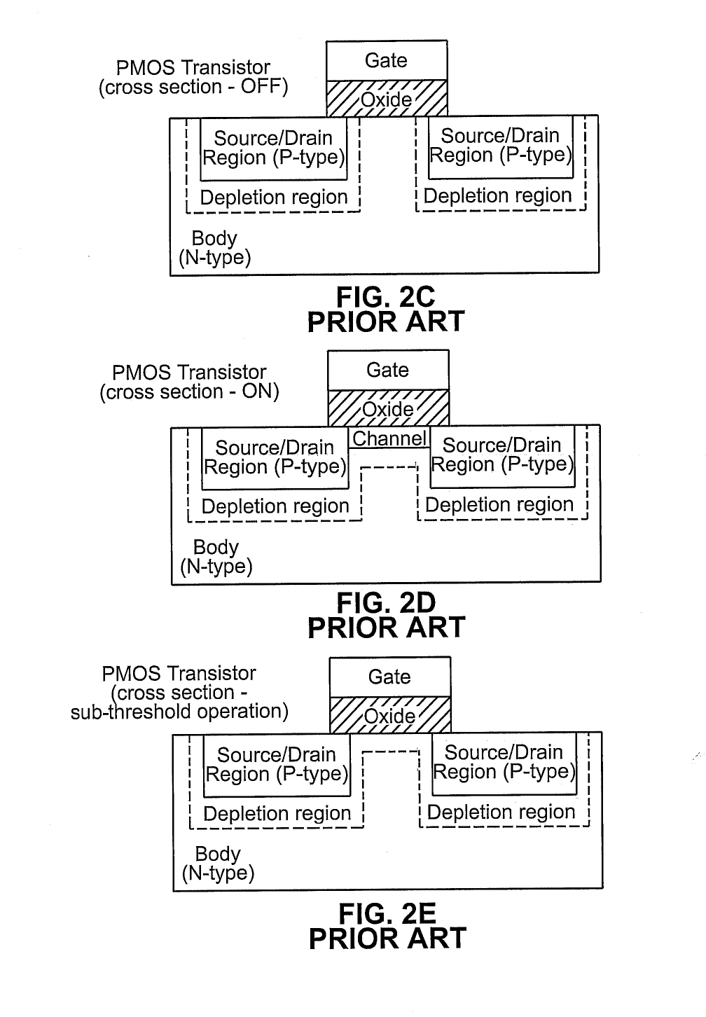

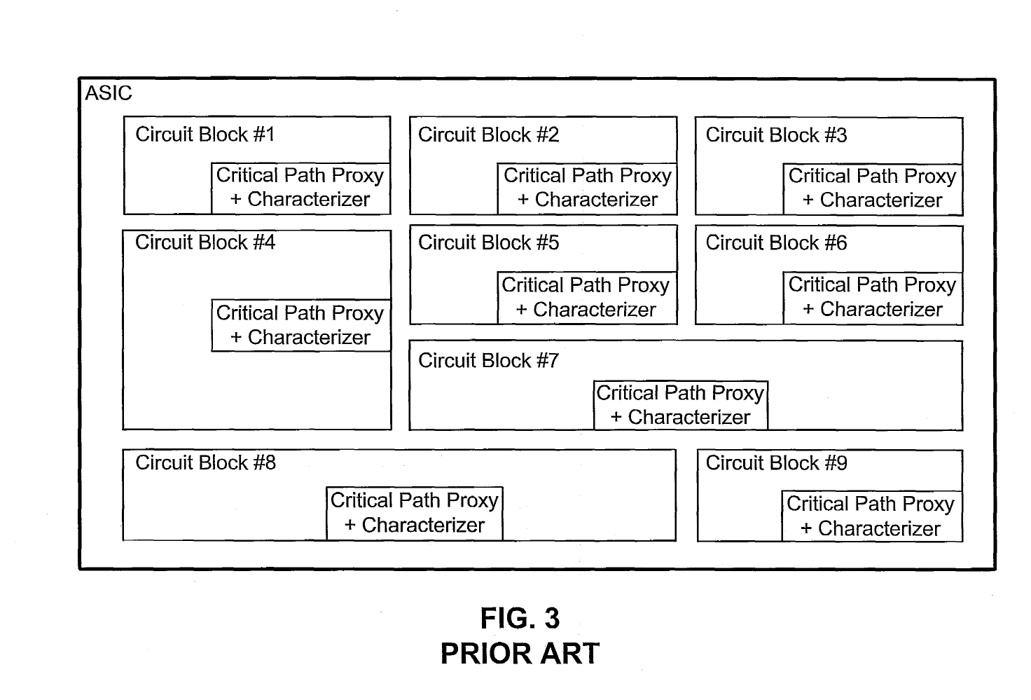

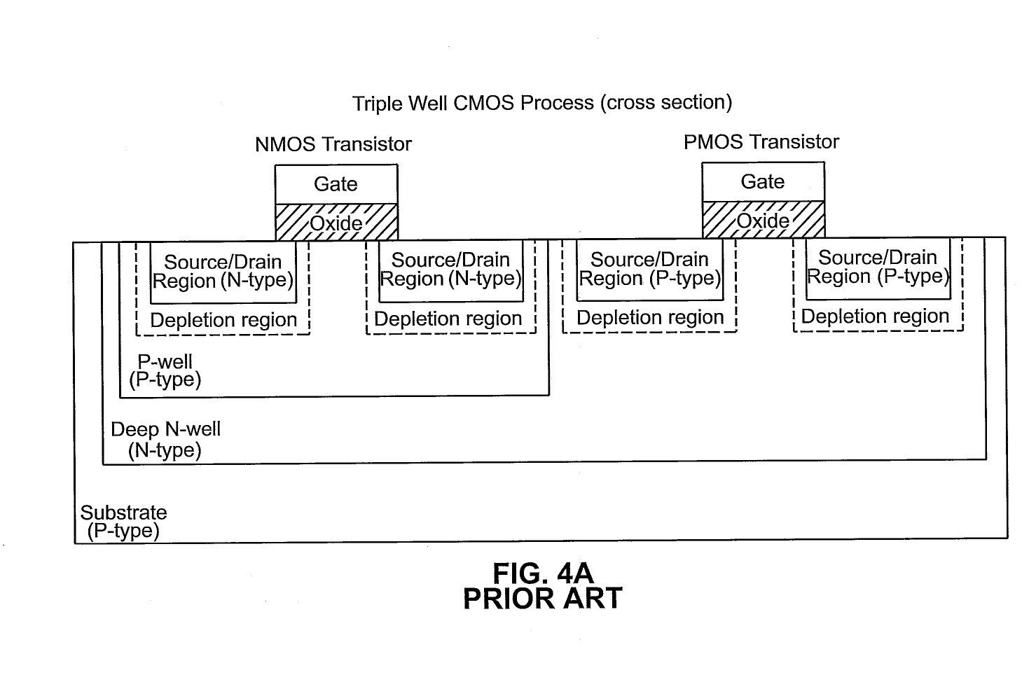

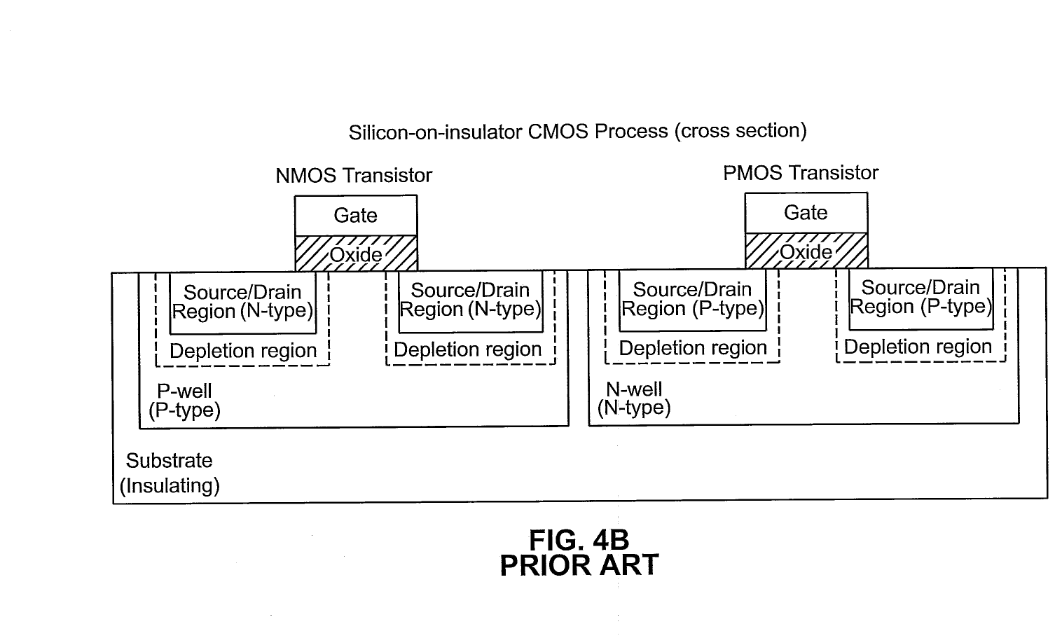

### DETAILED DESCRIPTION OF THE INVENTION

Those of ordinary skill in the art will realize that the following description of the present invention is illustrative only and not in any way limiting. Other embodiments of the invention will readily suggest themselves to such skilled persons.

A method for providing transistor threshold voltage compensation in an FPGA integrated circuit with a plurality of programmable circuit blocks includes measuring the effective transistor threshold voltage values of each programmable circuit block and adjusting the effective transistor threshold voltage values of each programmable circuit block to compensate for the difference between the measured effective transistor threshold voltage value and the target effective transistor threshold voltage value. Allowance can also be made for additionally reducing the leakage of blocks which are not part of a critical path in the user's design. Measuring the effective transistor threshold voltage value of a programmable circuit block is accomplished by, for example, measuring the propagation delay through a signal path inside that block or measuring the characteristics of individual transistors inside that block. Adjusting the effective transistor threshold voltage values of a programmable circuit block is accomplished by, for example, setting configuration bits coupled to that block or using body-biasing. The target effective transistor threshold voltage value can be the average effective transistor threshold voltage value for the FPGA, a value selected to optimize circuit performance, a value selected to minimize leakage, or selected for some other purpose.

A better understanding of the features and advantages of the present invention will be obtained by reference to the accompanying drawings, which set forth an illustrative embodiment and illustrative methods in which the principles of the invention are utilized.

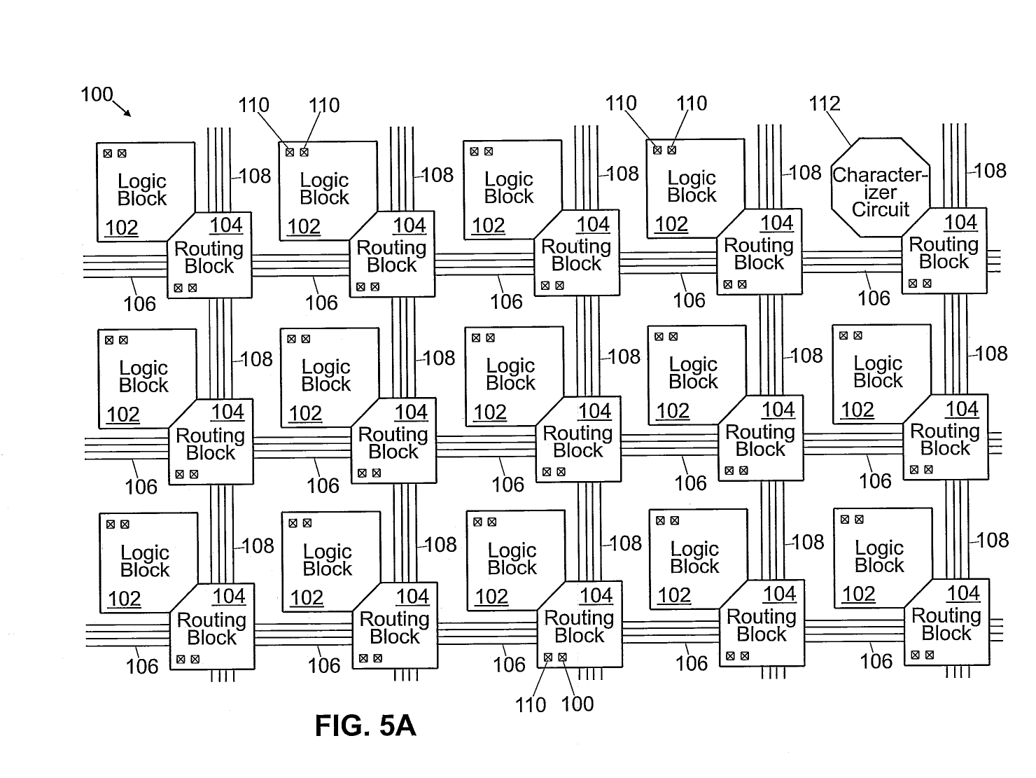

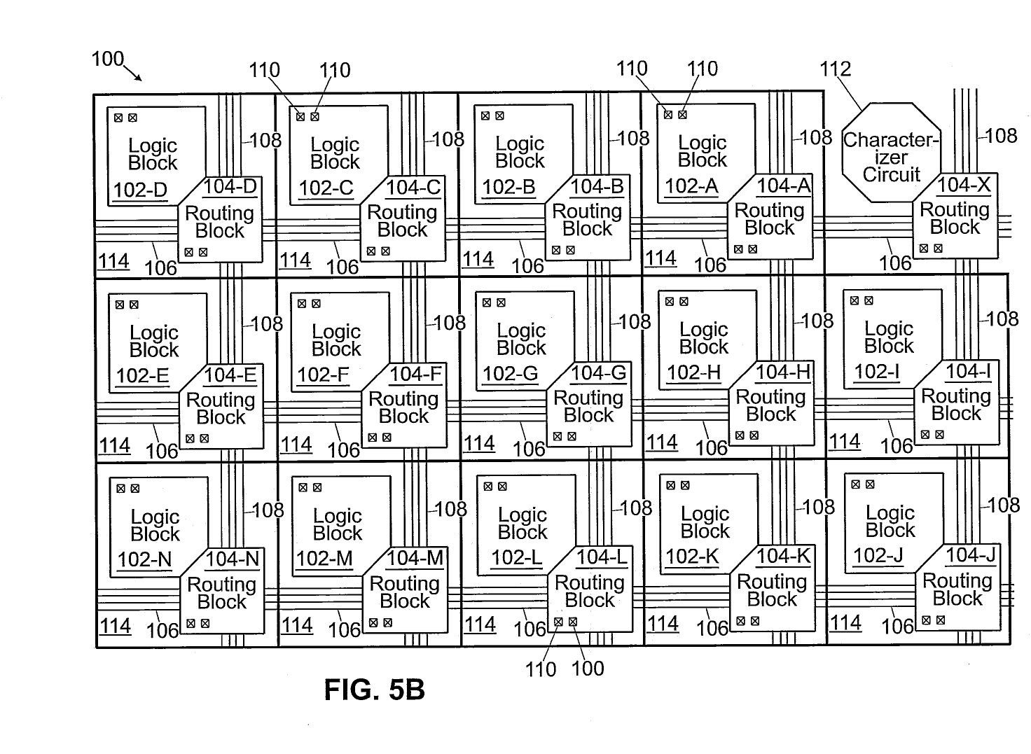

An illustrative FPGA architecture 100 suitable for use with the present invention is generally shown in FIG. 5A which shows its main components. There is an array of logic blocks 102 each coupled to a routing block 104. The logic blocks 102 perform the functions of a user's design while the routing blocks 104 provide the means for connecting signals between one logic block 102 and another. Illustrative horizontal interconnect wires 106 and illustrative vertical interconnect wires 108 are shown connecting each routing block 104 to its four adjoining routing blocks 104 on the North, South, East, and West sides. Each logic block 102 and routing block 104 has many configuration bits, most of which are not shown. Two configuration bits known as characterization bits 110 are shown associated with each logic block 102 and each routing block 104. Only a few of the characterization bits 110 are labeled to avoid over-complicating the figure. Persons skilled in the art will realize the choice of two characterization bits is illustrative only and is in no way limiting.

A logic block 102 along with its associated routing block 104 and its share of the connected horizontal interconnects 106 and vertical interconnects 108 form an illustrative repeatable tile. Use of a repeatable tile reduces the complexity of design and construction of the FPGA array while also simplifying many aspects of implementing the design software. The regularity of the array also facilitates certain aspects of testing. For example, in the ASIC microprocessor design disclosed by Tschanz, et al, every individual circuit block required its own characterizer circuit to determine the appropriate threshold voltage adjustment. Due to the regular nature of an FPGA array, all of the repeatable tiles are the same. Thus a single characterizer circuit can be used to measure the effective transistor threshold voltage of all of the programmable circuit blocks inside the FPGA array, which is substantially more efficient than the disclosed ASIC approach. Thus in FIG. 5A a single characterizer circuit 112 is shown.

In an FPGA of the present invention, a programmable circuit block is a sub-array of repeatable tiles comprising a portion of the FPGA array. The sub-array can be as small as 1×1 (a single repeatable tile) or be significantly larger as a matter of design choice. Given the programmable nature of the FPGA, in some embodiments of the present invention the size of the programmable circuit block can be determined at characterization time. For example, use of a larger programmable circuit block can reduce the measuring time but result in coarser granularity and potentially less accurate threshold voltage adjustments. For simplicity of discussion, we will hereafter assume that in the illustrative FPGA architecture 100 that a programmable circuit block is a single repeatable tile. Persons skilled in the art will realize this assumption is for illustrative purposes and does not limit the present invention in any way.

Turning to FIG. 5B, we see illustrative FPGA architecture 100 with the boundaries of the exemplary programmable circuit blocks 114 defined. Inside each programmable circuit block 114 we find a logic block 102 and a routing block 104. The reference numbers for the logic blocks 102 and routing blocks 104 have been given a letter suffix to facilitate discussion of individual logic blocks 102 and routing blocks 104 at specific locations in the FPGA array. Programmable circuit block 114 also includes the portion of the horizontal routing wires 106 and vertical routing wires 108 contained within its boundary. Characterization bits 110 are also present.

The characterizer circuit 112 selects each programmable circuit block in turn in order to measure its effective transistor threshold voltage and determine what the adjusted effective transistor threshold voltage should be. Then it selects another block and repeats the measurement and adjustment procedure, and so on until each block has been measured and adjusted.

It makes sense to speak of an Effective Transistor Threshold Voltage (henceforth ETTV) because there are many transistors in the speed paths of even the smallest programmable circuit block, and it is not practical to measure them all individually let alone attempt to analyze the implications of the individual random variations of each device. Rather, there needs be some way of evaluating the overall effect of all the different transistor threshold voltages as actually manufactured in a single programmable circuit block that simplifies down to a single number that serves as an overall rating for the block—and this is what is meant by the term ETTV.

In some embodiments of the present invention, the threshold voltage of sample transistors inside each programmable circuit block are directly measured and used as a proxy to infer the ETTV of the block. The circuitry to do this sort of measurement can be quite costly, since individual transistor characteristics must be controlled and measured. For example, one common technique for measuring threshold voltage is to assume the gate-to-source bias voltage at a small conduction current like, for example, one microampere is equal to the threshold voltage. The sample transistor is biased to force the assumed conduction current through the device while the gate-to-source bias voltage is measured. This approach is best employed in an FPGA that already has the necessary analog circuits for forcing currents and measuring bias voltages. For example, an FPGA using floating gate transistors as routing resources and control elements like the ProASIC3 family of FPGAs offered by Actel Corporation of Mountain View, Calif., makes use of analog measurements of floating gate transistor threshold values as part of the normal programming procedures. The analog circuitry supporting the floating gate technology could be modified to also measure conventional CMOS transistors and be employed to determine the ETTV of a programmable circuit block, thus reducing the cost of the direct measurement method.

In some embodiments of the present invention, the propagation delay through a signal path inside the programmable circuit block is measured and used as a proxy to infer the ETTV of the block. This assumption is appropriate because ultimately what matters to the end user is the propagation delay of signals through the block. It also simplifies the characterization process because measurements and adjustments can both be done in the time domain (i.e., measuring and adjusting block propagation delays) rather than in the voltage domain (i.e., measuring and adjusting transistor threshold voltages directly), eliminating the need for circuitry for translation between the two domains. To simplify the specification and avoid obscuring the inventive principles, the illustrative FPGA architecture described herein will assume the propagation delay method is to be used.

Returning to FIG. 5B, while characterizer circuit 112 is shown replacing a single logic block 102 in the illustrative architecture FPGA architecture 100, persons skilled in the art will realize other arrangements are possible and that the placement of the characterization circuit in FIG. 5B is in no way limiting. For example, the characterizer circuit area might larger than a single logic block 102 requiring it to replace more than a single logic block 102. As a matter of design choice, the characterization circuit might be located inside the FPGA integrated circuit device but placed outside of the FPGA array. In some FPGA architectures with, for example, non-volatile control elements, the characterizer circuit could be external to the integrated circuit. This would allow, for example, an external tester to function as the characterizer circuit and do the measurements, determine the appropriate adjustments, and program the characterization bits prior to the FPGA integrated circuit device leaving the factory.

Illustrative FPGA architecture 100 is completely generic. The repeatable tile can be clustered or flat, employ any logic module or mix of logic modules, use any sort of routing architecture with one or more levels of hierarchy, and be used with any technology and control element (like, for example, antifuses, SRAM bits, and floating gate transistors) whether volatile, non-volatile, one-time programmable, or reprogrammable. Any FPGA architecture can be modified to make use of the principles of the present invention. The simplicity and generality of the illustrative embodiments described herein is to avoid obscuring the inventive principles with descriptions of unnecessary detail. Persons skilled in the art will readily understand that the illustrative embodiments are exemplary only and in no way limiting.

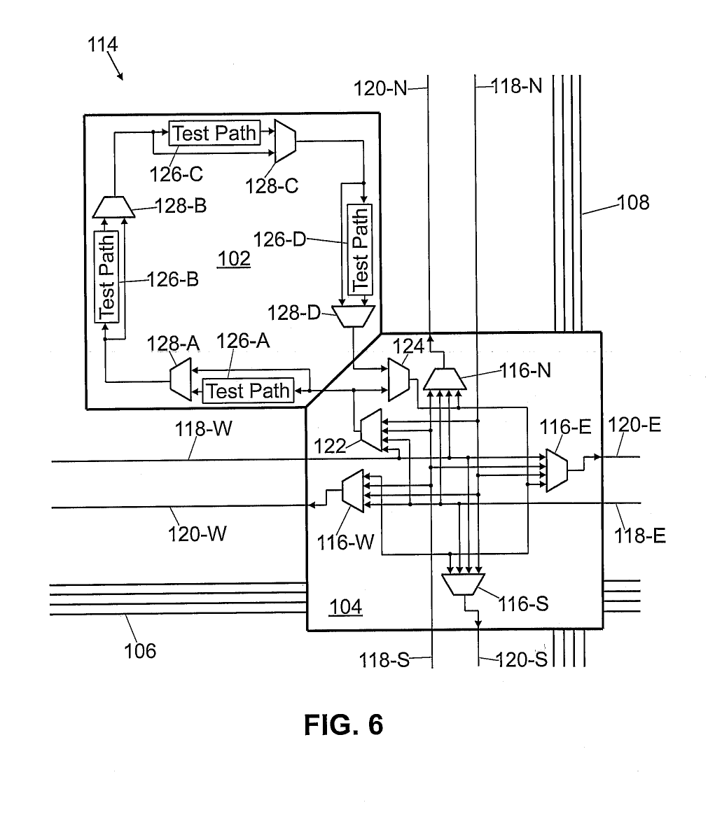

Programmable circuit block 114 is shown generally in FIG. 6. Present are logic block 102, routing block 104, horizontal interconnect wires 106, and vertical interconnect wires 108 that were previously described. Routing block 104 contains four input multiplexers 116-N, 116-E, 116-S, 116-W, and 122, and two input multiplexer 124 which are used by characterizer circuit 112 to facilitate the measurement of the ETTV for the programmable circuit block. Four input multiplexers 116-N, 116-E, 116-S, and 116-W have their output nodes coupled to output wires 120-N, 120-E, 120-S, and 120-W respectively. Four input multiplexer 116-N has its input nodes coupled to input wires 118-E, 118-S, 118-W, and the output node of two input multiplexer 124. Four input multiplexer 116-E has its input nodes coupled to input wires 118-S, 118-W, 118-N, and the output node of two input multiplexer 124. Four input multiplexer 116-S has its input nodes coupled to input wires 118-E, 118-N, 118-W, and the output node of two input multiplexer 124. Four input multiplexer 116-W has its input nodes coupled to input wires 118-N, 118-E, 118-S, and the output node of two input multiplexer 124. Four input multiplexer 122 has its input nodes coupled to input wires 118-N, 118-E, 118-S, and 118-W. The output node of two input multiplexer 122 is coupled to a first input of two input multiplexer 124, the input of test path 126-A and, a first input of two input multiplexer 128-A. Two input multiplexer 124 has its output node coupled to one input each of four input multiplexers 116-N, 116-E, 116-S, and 116-W, its first input node coupled to the output node of four input multiplexer 122, the input node of test path 126-A, and the first input node of two input multiplexer 128-A, and its second input node coupled to the output node of two input multiplexer 128-D.

Logic block 102 contains test paths 126-A, 126-B, 126-C, and 126-D and two input multiplexers 128-A, 128-B, 128-C, and 128-D. The input node of test path 126-A is coupled to the first input node of two input multiplexer 128-A, the first input node of two input multiplexer 124, and the output node of four input multiplexer 122. The output node of test path 126-A is coupled to the second input of two input multiplexer 128-A. The input node of test path 126-B is coupled to the first input node of two input multiplexer 128-B and the output node of two input multiplexer 126-A. The output node of test path 126-B is coupled to the second input of two input multiplexer 128-B. The input node of test path 126-C is coupled to the first input node of two input multiplexer 128-C and the output node of two input multiplexer 126-B. The output node of test path 126-C is coupled to the second input of two input multiplexer 128-C. The input node of test path 126-D is coupled to the first input node of two input multiplexer 128-D and the output node of two input multiplexer 126-C. The output node of test path 126-D is coupled to the second input of two input multiplexer 128-D.

Input wires 118-N, 118-E, 118-S, and 118-W are used to send test pulses or test clocks (collectively test signals) into programmable circuit block 114. Output wires 120-N, 120-E, 120-S, and 120-W are the means for sending test pulses or test clocks out of programmable circuit block 114. Input wires 118-N, 118-E, 118-S, and 118-W and output wires 120-N, 120-E, 120-S, and 120-W can be part of the normal FPGA routing resources or they can be dedicated resources specifically included for use with characterizer circuit 112 as a matter of design choice. Input wires 118-N, 118-E, 118-S, and 118-W and output wires 120-N, 120-E, 120-S, and 120-W are used in conjunction with four input multiplexers 116-N, 116-E, 116-S, and 116-W to pass test signals from one routing block 104 to its adjacent neighboring routing block 104 in the North, East, South, and West directions. For example, in FIG. 5B routing block 104-G has routing blocks 104-B, 104-H, 104-L, and 104-F as its North, East, South, and West nearest neighbors respectively.

Since programmable circuit blocks 114 are repeated in the illustrative FPGA architecture 100, input wires from one block are coupled to output wires from an adjacent nearest neighbor. Thus for routing block 104-G in FIG. 5B, input wire 118-N is coupled to output wire 120-S in routing block 104-B, input wire 118-E is coupled to output wire 120-W in routing block 104-H, input wire 118-S is coupled to output wire 120-N in routing block 104-L, input wire 118-W is coupled to output wire 120-E in routing block 104-F, output wire 120-N is coupled to output wire 118-S in routing block 104-B, output wire 120-E is coupled to output wire 118-W in routing block 104-H, output wire 120-S is coupled to output wire 118-N in routing block 104-L, and output wire 120-W is coupled to output wire 118-E in routing block 104-F.

Four input multiplexers 116-N, 116-E, 116-S, and 116-W are controlled by characterizer circuit 112 to send test signals out from the block in the North, East, South, and West directions respectively. Operation is completely symmetrical in all four compass directions. For example, consider the case of four input multiplexer 116-N. It can pass a test signal entering the block from the East, South, and West and direct it to the nearest neighbor to the North. Four input multiplexer 116-N in conjunction with two input multiplexer 124 can take a signal coming from inside logic block 102 and also direct it to the nearest neighbor to the North. If a loop-back is required on a signal coming in from the nearest neighbor to the North on input wire 118-N, it can be routed through four input multiplexer 122, two input multiplexer 124, and four input multiplexer 116-N and sent back on output wire 120-N. Four input multiplexers 116-E, 116-S, and 116-W perform exactly the same way, only the compass directions are rotated clockwise 90, 180, and 270 degrees respectively. This arrangement of multiplexers provides configuration circuit 112 the ability to send test signals to every programmable circuit block and every test path inside illustrative FPGA architecture 100 through a path of contiguous nearest neighbor programmable circuit blocks.

Logic block 102 is shown containing four test paths 126-A, 126-B, 126-C, and 126-D each with an associated two input multiplexer 128-A, 128-B, 128-C, and 128-D. The multiplexers are controlled by the characterizer circuit to either include or exclude a specific test path when test signals pass through logic block 102. Test paths 126-A, 126-B, 126-C, and 126-D may or may not be identical. In a first example embodiment, if there were four logic modules in logic block 102, each test path might comprise a single logic module. This would allow the characterizer circuit to determine the measured ETTV of programmable circuit block 114 by either sampling a fraction of the logic modules or by including all of them in the test path. This allows characterization time to be traded off against sampling accuracy in determining the adjusted ETTV for setting the characterization bits for the programmable circuit block 114. In a second example embodiment, each logic module has its own associated characterization bits allowing it to be adjusted separately from the other logic modules in programmable circuit block 114. The bypass multiplexers allow the characterization circuit to measure the effective ETTV of each logic module in turn and separately determine an adjusted ETTV on a per module basis. In a third example embodiment, each test path might represent a different type of logic module. One test path might contain nothing but function generators, another might contain sequential modules (like, for example, latches or flip/flops placed in a transparent mode so the test signals can pass through), a third might contain a carry chain associated with the function generators to make adders, and so on. If each type of logic module has its own characterization bits, then each module type could have its ETTV measured and adjusted separately. The presence of four test paths is illustrative only and the exact number and type employed in logic block 102 in an FPGA architecture 100 built according to the principles of the present invention is a matter of design choice and in no way limiting. Other embodiments will suggest themselves to persons skilled in the art. For example, additional test paths (not shown in FIG. 6 to avoid overly complicating the figure) could be included inside routing block 104 with appropriately placed multiplexers to allow for characterizing the ETTV of routing block 104 separately from logic block 102.

As previously described, the characterizer circuit 112 selects each programmable circuit block in a sequence in order to measure its effective transistor threshold voltage and determine what the adjusted effective transistor threshold voltage should be. The sequence could be fixed or variable as a matter of design choice. Typically the first programmable circuit block selected would be adjacent to the characterizer circuit because of the easy accessibility. In the illustrative FPGA architecture 100 in FIG. 5B, the characterizer circuit 112 is shown with its own associated routing block 104-X. If the programmable circuit block 114 containing routing block 104-A is the first programmable circuit block to be selected in an exemplary sequence, the characterizer circuit 112 will configure the appropriate multiplexers in routing blocks 104-X and 104-A and logic block 102-A to route test signals from the characterizer circuit through routing blocks 104-X and 104-A, through the desired test path or test paths inside logic block 104-A, back through routing blocks 104-A and 104-X, and back into the characterizer circuit 112.

If programmable circuit block 114 containing routing block 104-B is the second programmable circuit block in the exemplary sequence, the characterizer circuit 112 will configure the appropriate multiplexers in routing blocks 104-X, 104-A and 104-B and logic block 102-B to route test signals from the characterizer circuit through routing blocks 104-X, 104-A, and 104-B, through the desired test path or test paths inside logic block 104-B, back through routing blocks 104-B, 104-A and 104-X, and back into the characterizer circuit 112. The exemplary sequence could continue Westward with each successive block in the North most row in the FPGA array all the way to the end, go South one row, turn Eastward along the middle row of the FPGA array all the way to the end, go South one row, and turn Westward along the South most row of the FPGA array all the way to the end until the last block is characterized.

Persons skilled in the art will realize that other sequences are possible and that the exemplary sequence above in no way limits the scope of the present invention. For example, a second exemplary sequence is to do all the blocks in each row starting with the East most block and proceeding West until the West most block is characterized, and then repeat that procedure for each row starting with the North most row and proceeding South until all the blocks in the South most row are characterized. Indeed such skilled persons will realize that the blocks could be done in any order and that the order of the sequence is a matter of design choice.

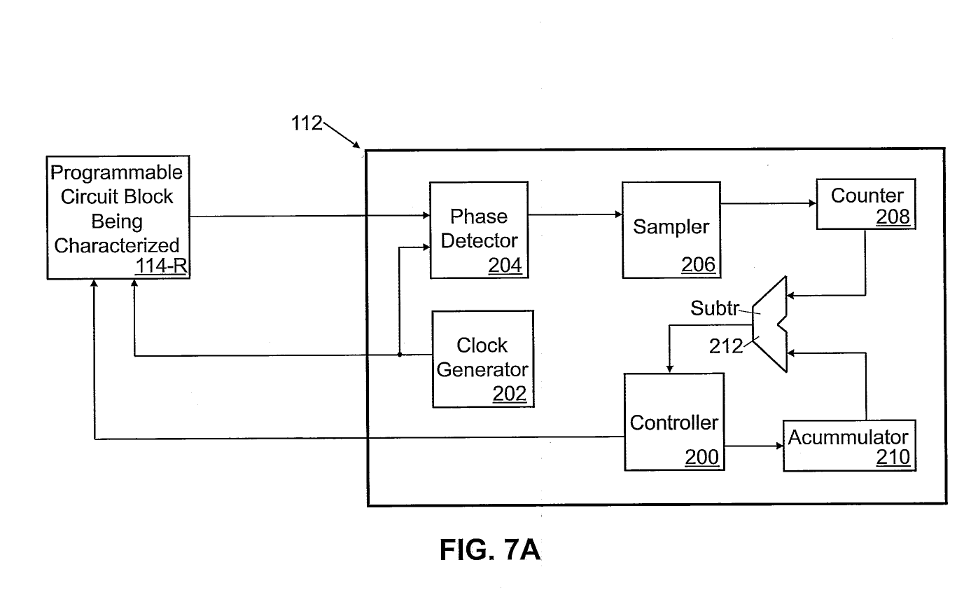

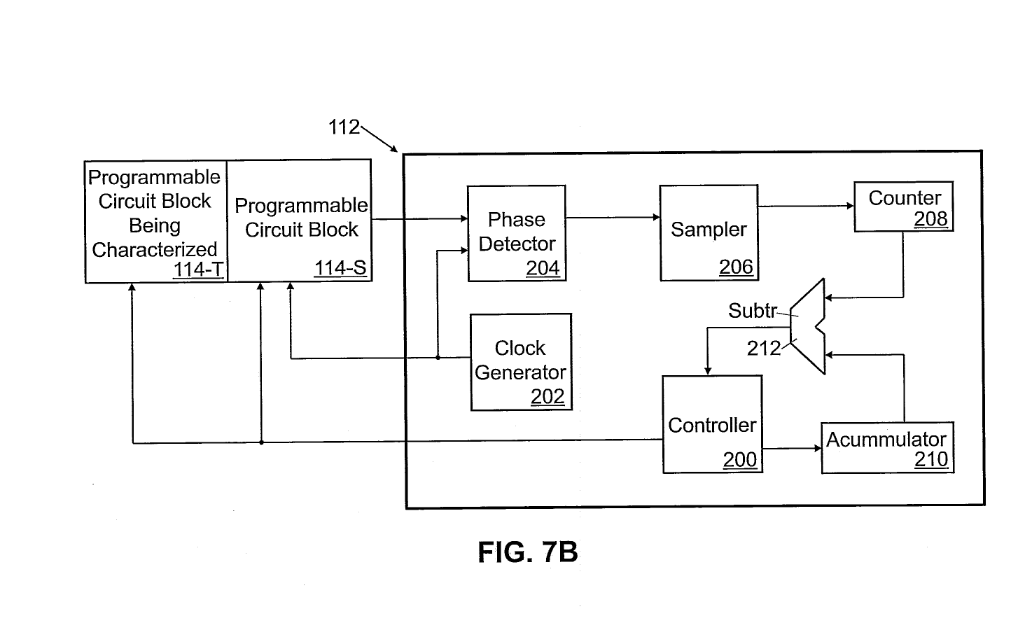

FIG. 7A shows characterizer circuit 112 along with its major sub-circuits coupled to a programmable circuit block 114-R being characterized. Characterizer circuit 112 comprises controller 200, clock generator 202, phase detector 204, sampler 206, counter 208, accumulator block 210, and subtractor 212. Controller 200 oversees the entire measurement and adjustment procedure. It is coupled to every block either explicitly as shown in FIG. 7A or by means of control signals not shown to avoid over-complicating the figure. Controller 200 may be a finite state machine or constructed using some other logic technique. Controller 200 is also coupled to every programmable circuit block 114 inside the FPGA array either explicitly as shown in FIG. 7A or by means of control signals not shown in order to control the various multiplexers shown in FIG. 6.

Clock generator 202 is coupled to programmable circuit block 114-R and phase detector 202. Clock generator 202 produces the test pulses or test clocks used to measure the propagation delays through programmable circuit block 114-R. A test pulse may be a signal comprising a single transition from logic-0 to logic-1 and a single transition from logic-1 to logic-0. The order of the transitions is a matter of design choice. A test clock may be a series of test pulses spread out uniformly in time. The use of test pulses or test clocks is a matter of design choice depending on a number of factors like, for example, the nature and construction of phase detector 204, the clock frequency employed internal to clock generator block 202, the clock frequency employed internal to sampler 206, and the length of the delay to and from programmable circuit block 114-R.

Phase discriminator 204 has a first input node coupled to programmable circuit block 114-R, a second input node coupled to clock generator 202, and an output node coupled to sampler 206. Phase discriminator 204 can be built using any number of techniques known in the art. Phase discriminator 204 monitors logic-0 to logic-1 signal transitions on its two inputs and produces a logic-1 pulse on its output node that has a duration in time proportional to the time difference between the transitions on its inputs. The use of logic-0 to logic-1 transitions on the inputs and a logic-1 pulses on the outputs in the construction of phase discriminator 204 is a matter of design choice and logically complimentary transitions and pulses could just as easily be used for some or all of the nodes.

Sampler circuit 206 has an input node coupled to phase discriminator 204 and an output node coupled to counter 208. Internal to sampler 206 is a high speed clock source. Sampler 206 outputs a pulse with a logic-0 to logic-1 transition followed by a logic-1 to logic-0 transition on its output node every internal clock cycle when its input node is logic-1 and outputs a logic-0 on its output node every internal clock cycle when its input node is at logic-0. The number of pulses is proportional to the output pulse from the phase discriminator which in turn is proportional to the time difference detected on the inputs of phase discriminator 204. The logic polarities described are a matter of design choice and complimentary logic polarities could just as easily be used on any node as long as logical consistency is maintained in the entire design of characterizer circuit 112.

Counter circuit 208 is a binary counter of a type known in the art that has a clock input node coupled to sampler 206 and an output bus comprising a number of binary bits coupled to the first input bus of subtractor 212. Controller 200 resets the binary value to zero in counter 208 in preparation for making a measurement. Counter 208 increments every time it receives a clock pulse from sampler 206. This means at the end of a measurement the binary value in the counter will equal the number of pulses output from sampler 206 which is proportional to the width of the pulse output from phase discriminator 204 which is proportional to the difference in time between the signal transitions on the inputs of phase discriminator which is proportional to the propagation delay from clock generator 202 through programmable circuit block 114-R and back to phase discriminator 204. Thus the binary value contained in counter 208 is the quantized value of the propagation delay of the entire test path.

Accumulator circuit block 210 has an input bus coupled to controller 200 and an output bus coupled to the second input bus of subtractor 212. It is used by controller 200 to eliminate any excess delay (or delay error) contained in the value in counter 208. Delay error can occur due to the time needed to propagate the test signals to and from programmable circuit block 114-R. Such delay error could result from, for example, resistive and capacitive delays in the wires coupling the controller 200 to the programmable circuit block 114-R, or by the need to transmit the test signals through previously characterized blocks as described in conjunction with FIG. 5B and FIG. 6. Prior to making the measurement, controller 200 must determine the value of the delay error and insure the correct value is presented on the output bus of accumulator 210. Controller 200 may make a separate measurement of the path to and from programmable circuit block 114-R using a loop-back to determine the propagation delay of the test signals to and from the block being characterized. Alternatively, controller 200 may save the value of the previous measurement, if any, in accumulator 210 and use the difference between that value and the current measured delay as the measured value for the current block being characterized. This latter technique can be thought of as effectively accumulating (or summing) the individual error terms from all previously measured blocks (hence the name of the block) into the total delay error. The actual approach used is a matter of design choice and depends on a number of factors like, for example, the sequence in which the blocks are to be characterized, the location of the currently selected block in the sequence, the number of repeatable tiles contained in the programmable circuit block, the nature of the test paths inside the programmable circuit block, and trade-offs between characterization time and the coarseness of sampling and or adjusting if the programmable circuit block size is variable.

Subtractor circuit block 212 is a binary subtractor circuit of a type known in the art. It has a first input bus coupled to counter 208, a second input bus coupled to accumulator block 210, and an output bus coupled to controller 200. It does a binary subtraction of the value in accumulator 210 from the value in counter 208 and presents the outputs to controller 200 for processing. This value corresponds to the measured ETTV value of the currently selected block since the subtractor removes the error term contained in accumulator block 210.

In this illustrative embodiment the propagation delay through a block is used as a proxy for the measured ETTV. Once the value of the measured ETTV is determined, it must be evaluated by controller 200 to determine the value for the adjusted ETTV for the block. This is done by comparing the measured ETTV to a target ETTV which in turn must be chosen with regards to the distribution of random within-die threshold voltage variations.

Empirical evidence indicates that the distribution of transistor threshold voltage variations follows the normal distribution probability function (also known as a Gaussian distribution or, more popularly, as a bell curve) that is well known in statistics. The normal distribution curve can be thought of as a histogram where the X-axis represents the values of the parameter being measured—in this case the transistor threshold voltage. The area under the curve between any two points on the X-axis represents the portion of the population being sampled that is expected to occur in that range of values. The shape of the normal distribution curve depends on its mean (the value on the X-axis at the peak of the curve—in this case the average transistor threshold value for the CMOS process being used) and its standard deviation (the distance from the mean on the X-axis where the inflexion point of the curve occurs—in this case some amount of voltage above or below the average threshold voltage which is also determined by the CMOS process). The standard deviation is sometimes referred to by the Greek letter sigma. According to the normal distribution function, 68.3 percent of a population fall within one standard deviation from the mean (or +/−1 sigma), 95.4 percent of a population fall within two standard deviations of the mean (or +/−2 sigma), and 99.7 percent of a population fall within three standard deviations of the mean (or +/−3 sigma). Most CMOS design methodologies employed in the semiconductor industry allow for +/−three sigma variations in transistor parameters, which means that 997 parts out of 1,000 should fall within anticipated process variations for any given transistor parameter.

Empirical evidence also indicates that there is a linear relationship between incremental CMOS circuit propagation delays and incremental changes in transistor threshold voltage. This means that controller circuit 200 can easily make adjustments to the threshold voltage due to this linear behavior by simple addition and subtraction of delay values.

In some embodiments of the present invention, each programmable circuit block 114 has some number of characterization bits used for controlling the transistor threshold voltage levels in that block. In other embodiments, various sub-circuits inside the programmable circuit block can have their own sets of characterization bits and can have their threshold voltages be independently adjusted.

The number of characterization bits per circuit or sub-circuit is a matter of design choice, though two or three are sufficient in most applications. This would allow up to four or eight different transistor threshold voltage levels in the circuit or sub-circuit being adjusted. For simplicity, it is desirable to employ an odd number of levels so that one of the levels corresponds to the center of the adjustment range and there are an equal number of adjustment points on either side of the center. Thus three or five or seven adjustment points would typically be used. Persons skilled in the art will realize that there is an engineering trade-off to be made between the accuracy of transistor threshold voltage adjustment (the more bias levels employed, the more accurately variations can be corrected) versus the hardware cost (the more bias levels employed, the more voltage levels need to be generated and distributed). Such skilled persons will realize the number of characterization bits and bias levels selected in any given embodiment in no way limits the present invention.

The value of the target ETTV can be chosen for any of a number of reasons. For example, the target ETTV could correspond to the mean transistor threshold voltage for the NMOS and PMOS transistors in the particular CMOS fabrication facility where the FPGA integrated circuit device was manufactured. Thus, for example, in an embodiment with three ETTV levels, the middle ETTV level could be set to the mean ETTV value for the CMOS process and the other two levels could be set to some number of standard deviations above and below the average as a matter of design choice. Since the illustrative FPGA architecture 100 described herein uses the propagation delay method of determining measured ETTV, above average measured ETTV would mean a longer propagation delay through a programmable circuit block or sub-circuit. Longer delays correspond to NMOS and PMOS transistors with higher absolute values of threshold voltage and thus lower levels of leakage. Similarly, below average ETTV would mean a shorter propagation delay through a programmable circuit block or sub-circuit. Shorter delays correspond to NMOS and PMOS transistors with higher absolute values of threshold voltage and thus lower levels of leakage.

For example, if a +/−1.5 sigma shift is selected, circuits or sub-circuits with a measured ETTV value between the mean ETTV minus 1.5 sigma and the mean ETTV plus 1.5 sigma would receive no transistor threshold voltage adjustment at all. Circuits or sub-circuits with a measured ETTV value less than the mean ETTV minus 1.5 sigma would have their adjusted ETTV values shifted upward by an amount corresponding to 1.5 sigma, while circuits or sub-circuits with a measured ETTV value more than the mean ETTV plus 1.5 sigma would have their adjusted ETTV values shifted downward by an amount corresponding to 1.5 sigma.

A larger number of ETTV levels can be used to produce an even tighter post-adjustment distribution. Thus, for example, in an embodiment with seven ETTV levels the adjustment ranges could be smaller. For example, if a one sigma per level shift is selected the middle ETTV level could be set to the range between the mean ETTV value minus 0.5 sigma and the mean ETTV value plus 0.5 sigma. Circuits and sub-circuits with measured ETTV values within this range would receive no adjustment. Circuits or sub-circuits with measured ETTV values below this range would receive a +1 sigma, +2 sigma, or +3 sigma ETTV adjustment, while circuits or sub-circuits with measured ETTV values above this range would receive either a −1 sigma, −2 sigma, or −3 sigma ETTV adjustment. Thus, for example, a circuit or sub-circuit with a measured ETTV value below −2.5 sigma would get a +3 sigma adjustment, a circuit or sub-circuit with a measured ETTV value between −2.5 sigma and −1.5 sigma would get a +2 sigma adjustment, a circuit or sub-circuit with a measured ETTV value between −1.5 sigma and −0.5 sigma would get a +1 sigma adjustment, a circuit or sub-circuit with a measured ETTV value between +0.5 sigma and +1.5 sigma would get a −1 sigma adjustment, a circuit or sub-circuit with a measured ETTV value between +1.5 sigma and +2.5 sigma would get a −2 sigma adjustment, and a circuit or sub-circuit with a measured ETTV value above +2.5 sigma would get a −3 sigma adjustment.

Choosing the process mean ETTV as the target ETTV, allows tightening of the normal power and performance distributions inherent in the CMOS process. This can be used to produce a device with narrower specified ranges than would otherwise be possible and allow the design software to more aggressively utilize FPGA resources.

The controller 200 can operate on the measured ETTV values in a different manner. For example, if a manufacturer wishes to produce a low-power version of the FPGA, the controller 200 could operate to skew the distributions to higher values of ETTV without danger of over compensating. For example, in an embodiment with three adjustment levels the target voltage could be set to the mean ETTV but negative corrections would not be allowed. Thus a circuit or sub-circuit that would normally receive no adjustment would still receive no adjustment, a circuit or sub-circuit that would normally have received a positive adjustment would still receive that adjustment, and a circuit or sub-circuit that would have normally received a negative adjustment would receive no adjustment at all.

Alternatively, a more aggressive approach towards achieving a low-power version of the FPGA could be taken with the controller 200. For example, in an embodiment with three adjustment levels a circuit or sub-circuit that would normally receive no adjustment would receive a positive adjustment, a circuit or sub-circuit that would normally have received a positive adjustment would still receive that adjustment, and a circuit or sub-circuit that would have normally received a negative adjustment would receive no adjustment at all.

In a similar manner, the controller 200 could be used to generate a high-performance version of the FPGA by taking the exact opposite action as it would have in either the less aggressive or more aggressive low-power cases and skewing the ETTV values lower rather than higher.

There are reasons that some voltage other than the mean ETTV would be used as the target value as a matter of design choice. For example, a manufacturer attempting to create a low-power version of the FPGA might employ an embodiment with seven ETTV levels which are 1 sigma wide which we will name (according the center of each of the ETTV adjustment range in sigmas, specifically −3 sigma, −2 sigma, −1 sigma, 0 sigma, +1 sigma, +2 sigma, and +3 sigma which will be abbreviated as −3, −2, −1, 0, +1, +2, and +3 in the examples below). As previously discussed, if the target ETTV is 0 (the mean of the distribution), circuits or sub-circuits with measured ETTV values −3, −2, −1, 0, +1, +2, and +3 sigma ranges would have adjusted ETTV values of 0, 0, 0, 0, 0, 0, and 0 respectively.

If, however, the target ETTV value is set to +1 sigma, then an adjusted ETTV distribution range pattern of 0, +1, +1, +1, +1, +1, and +1 would result. The first 0 for the blocks in the −3 sigma range is because the very fastest blocks (and thus the blocks with the highest leakage and lowest ETTV) can only be corrected by a value of +3 and never make it into the target adjusted ETTV range of +1.

The controller 200 could be used more aggressively in favor of low-power, but at the cost of a wider distribution. If the target ETTV value corresponding to +2 sigma is used, the distribution range pattern would be 0, +1, +2, +2, +2, +2, and +2. In this case, the blocks with measured ETTV values in the −2 and −3 sigma ranges can not be corrected all the way to the +2 sigma range.

In a similar manner, a manufacturer could use a target ETTV lower than the process mean ETTV to create a high-performance version of the FPGA in an entirely analogous manner. Other ways of manipulating the controller 200 with regards to target ETTV and width of adjustment range will suggest themselves to persons skilled in the art. Thus the above examples should be considered illustrative only and in no way limiting of the present invention.

Once controller 200 has measured the ETTV value for a circuit or sub-circuit and determined the appropriate adjusted ETTV, it must apply this value to the circuit or sub-circuit for when the FPGA enters normal operating mode. In some embodiments the adjusted data can be stored in a memory and then applied to all of the circuits, and sub-circuits after the characterization process is completed. In some embodiments the measured data can be stored in a memory and the adjusted ETTV determined at the time of application. The sequence of application may or may not be the sequence in which the ETTV of the circuits or sub-circuits was measured. The memory could either be part of the FPGA integrated circuit device, or it could be external. In other embodiments, the adjusted values can be applied to the block at the time of characterization. This has the advantage of not needing a large amount of memory, and the disadvantage of changing the measured ETTV value of the just measured circuitry if further test signals are to be propagated through that same circuitry. Thus if the characterization bits are set at the time of characterization, another measurement may be necessary to properly calibrate the value in the accumulator block 210. Alternatively, the programmable circuit block could be designed so that some of the circuits like, for example, the various test signal routing multiplexers, do not have their ETTV adjusted by the characterization bits. Persons skilled in the art will realize that the choice of the time of programming the characterization bits and choosing not to adjust the ETTV of all sub-circuits inside a programmable circuit block will depend on a number of different factors like, for example, whether the technology employed in the FPGA is volatile or non-volatile, whether the technology is reprogrammable or one-time programmable, whether the characterization is taking place in the factory or inside an end user's system, and the cost of characterization time. Such skilled persons will realize that this choice in no way limits the scope of the present invention.

In a preferred embodiment of the present invention the adjusted ETTV values are applied to the FPGA circuitry utilized by the end user's design by means of adaptive body-biasing. The characterization bits control analog multiplexers that couple the body terminals of the transistors to generated bias voltages of the appropriate values for producing the desired threshold voltage in the transistors. The bias voltage generators are constructed from analog circuits of a type well known in the art like, for example, charge pumps, operational amplifiers, and digital-to-analog converters. Because of the size of these circuits they will be shared by all of the programmable circuit blocks 114 on the entire chip and the outputs of the bias voltage generators will be coupled to each programmable circuit block 114. Persons skilled in the art will recognize that other methods for generating and distributing the bias voltages like, for example, generating the bias voltages external to the FPGA, using analog buffers as part of the distribution scheme, or attempting to mimic the variations in transistor threshold voltages in some other way like, for example, having multiple power supplies and using power supply multiplexers controlled by the characterization bits to couple the different programmable circuit blocks 114 to the different power supplies. Such skilled persons will also realize that all such methods fall within the inventive principles of the present invention and that a preference for using adaptive body-biasing is in no way limiting.

FIG. 7B shows characterizer circuit 112 and programmable circuit blocks 114-S and 114-T. In the figure, controller 200 is shown coupled to programmable circuit block 114-S and programmable circuit block 114-T, clock generator 202 is shown coupled to phase detector 204 and programmable circuit block 114-S, and programmable circuit block 114-S is shown coupled to phase detector 204. In this particular arrangement, programmable circuit block 114-T is the block selected for characterization, but since it is not adjacent to characterizer circuit 112, the test signals must pass through programmable circuit block 114-S twice, once in order to reach programmable circuit block 114-T and a second time to return to phase discriminator 204.

Controller 200 controls the relevant portions of both programmable circuit block 114-S and programmable circuit block 114-T in order to successfully do this. This could be done by the means of control wires coupled to all of the blocks as shown in the diagram, but other approaches are possible. For example, if the FPGA uses SRAM bits as the control elements, then the relevant control bits could be arranged in a manner that the controller can write them using the normal programming circuitry. In technologies like antifuse and floating gate transistors where programming control elements is more complicated, another scheme like including control registers in each programmable circuit block 114 that can be read or written by means of a microprocessor-style address bus and a data bus could be employed. Alternatively, one or more shift register chains running through all of the programmable circuit blocks 114 in the FPGA could be employed by controller 200. Other methods for controlling the characterization process will suggest themselves to persons skilled in the art. Such skilled persons will realize that the presence of a single programmable circuit block 114-S between characterizer circuit 112 and the programmable circuit block 114-T being characterized is illustrative only and that any number of contiguous programmable circuit blocks 114 can be located between characterizer circuit 112 and the programmable circuit block 114-T being characterized. Such skilled persons will also realize that many FPGA architectures include rows, columns, or areas containing special blocks like, for example, embedded microprocessor blocks and static random-access memory (SRAM) blocks, and that routing resources, control signals, and test routinely pass through these special blocks and areas making programmable circuit blocks on both sides of the special block or area substantially contiguous with respect to each other.

Once the adjusted ETTV values have been determined for a programmable circuit block, a further refinement is possible. Empirical evidence suggests that on average 75% of all FPGA routing resources can have their speed reduced by as much as 50%. This means that programmable circuit blocks 114 or their sub-circuits can have their ETTV values adjusted downward if they are not on a critical path in the end user's design. This information may come from a designation by the end user or be determined by the design software. This information can be stored in configuration bits inside programmable circuit block 114 and be used to make an appropriate shift in the adjusted ETTV at very little incremental cost in area. The adjustment could take the form of a shift towards a lower sigma range by means of subtracting the leakage adjustment from the characterized adjusted ETTV. Alternatively a truncation operation could prevent a value higher than the value in the leakage bits or the leakage bits could simply force the lowest possible ETTV state. Other ways of doing a low-leakage adjustment will readily suggest themselves to persons skilled in the art, and the suggested methods here are illustrative only and in no way limiting.

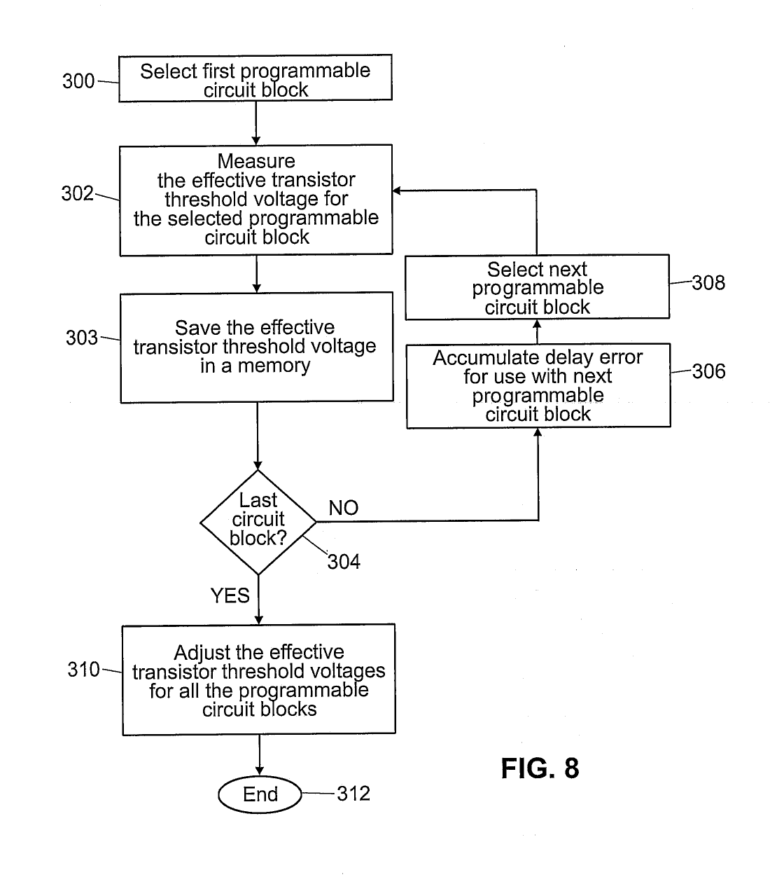

FIG. 8 shows a first illustrative method of implementing an FPGA in accordance with the present invention. Step 300 is to select the first programmable circuit block in the characterization sequence and then proceed to step 302. Step 302 is to measure the ETTV value of the selected block and then proceed to step 303. Step 303 is to save the ETTV value of the selected block in a memory and then proceed to step 304. If programmable circuit block 114 has sub-circuit blocks that can be characterized separately from each other and are coupled to their own separate characterization bits, then step 302 includes measuring the ETTV values for each separately characterizable sub-circuit. Step 304 makes a determination as to whether the currently selected programmable circuit block 114 is the last block in the characterization sequence. If step 304 determines the selected programmable circuit block 114 is the last block, then step 304 proceeds to step 310, otherwise step 304 proceeds to step 306.

Step 310 applies the adjusted ETTV values to the programmable circuit blocks 114 and their sub-circuits, if any, and then proceeds to step 312. Step 312 is the end of the method.

Step 306 accumulates the appropriate error value for use with the next selected programmable circuit block 114 and then proceeds to step 308. Step 308 selects the next programmable circuit block 114 and then proceeds back to step 302. The method cycles through steps 302, 304, 306, and 308 for each programmable circuit block 114 in the characterization sequence until step 304 determines the last programmable circuit block 114 has been characterized and then exits the loop by proceeding to step 310.

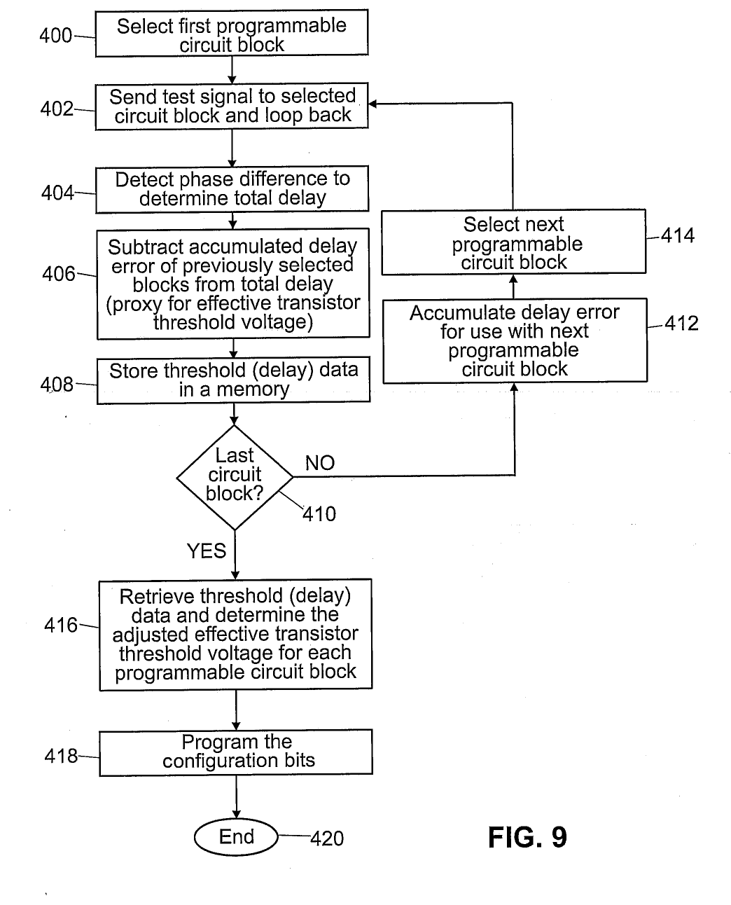

FIG. 9 shows a second illustrative method of implementing an FPGA in accordance with the present invention. Step 400 is to select the first programmable circuit block in the characterization sequence and then proceed to step 402. Step 402 sends a test signal from characterizer circuit 112 through the selected programmable circuit block 114 then loops it back to characterizer circuit 112. Step 402 then proceeds to step 404. Step 404 detects the phase difference between the outgoing and returning test signal to determine the total propagation delay of the test path and then proceeds to step 406. Step 406 subtracts the accumulated delay from previously selected blocks, if any, to determine the measured delay of the selected programmable circuit block 114, which is a proxy for the ETTV and then proceeds to step 408. Step 408 stores the measured delay value in some sort of memory for later retrieval and then proceeds to step 410. Step 410 makes a determination as to whether the currently selected programmable circuit block 114 is the last block in the characterization sequence. If step 410 determines the selected programmable circuit block 114 is the last block, then step 410 proceeds to step 416, otherwise step 410 proceeds to step 412.

Step 416 retrieves the data stored in memory in step 408 and processes it to determine the adjusted ETTV for each programmable circuit block 114 and then proceeds to step 418. Step 418 programs the characterization bits for each programmable circuit block 114 and proceeds to step 420. Step 420 is the end of the method.

Step 412 accumulates the appropriate error value for use with the next selected programmable circuit block 114 and then proceeds to step 414. Step 414 selects the next programmable circuit block 114 and then proceeds back to step 402. The method cycles through steps 402, 404, 406, 408, 410, 412, and 414 for each programmable circuit block 114 in the characterization sequence until step 410 determines the last programmable circuit block 114 has been characterized and then exits the loop by proceeding to step 416.

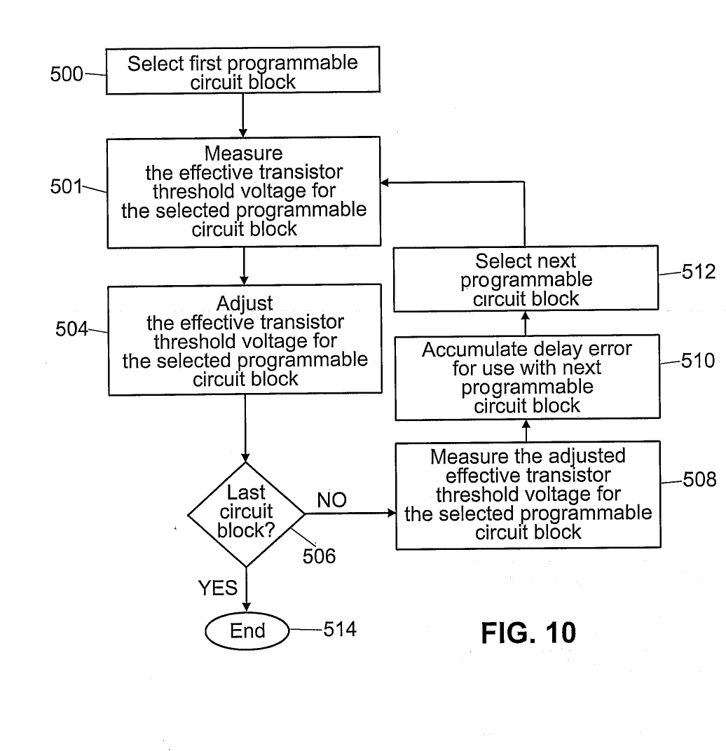

FIG. 10 shows a third illustrative method of implementing an FPGA in accordance with the present invention. Step 500 is to select the first programmable circuit block in the characterization sequence and then proceed to step 502. Step 502 is to measure the ETTV value of the selected programmable circuit block 114 and then proceed to step 504. If programmable circuit block 114 has sub-circuit blocks that can be characterized separately from each other and are coupled to their own separate characterization bits, then step 502 includes measuring the ETTV values for each separately characterizable sub-circuit. Step 504 determines the adjusted ETTV value or values based on the measured ETTV value or values and applies the adjusted ETTV value or values to the programmable circuit blocks 114 and their sub-circuits, if any, and then proceeds to step 506. Step 506 makes a determination as to whether the currently selected programmable circuit block 114 is the last block in the characterization sequence. If step 506 determines the selected programmable circuit block 114 is the last block, then step 506 proceeds to step 514, otherwise step 506 proceeds to step 508. Step 514 is the end of the process.

Step 508 measures the adjusted effective transistor threshold voltage for the selected programmable circuit block and proceeds to step 510. Step 510 accumulates the total adjusted delay for use with the next circuit block and proceeds to step 512. Step 512 selects the next programmable circuit block 114 and then proceeds back to step 502. The method cycles through steps 502, 504, 506, 508, 510, and 512 for each programmable circuit block 114 in the characterization sequence until step 506 determines the last programmable circuit block 114 has been characterized and then exits the loop by proceeding to step 514.

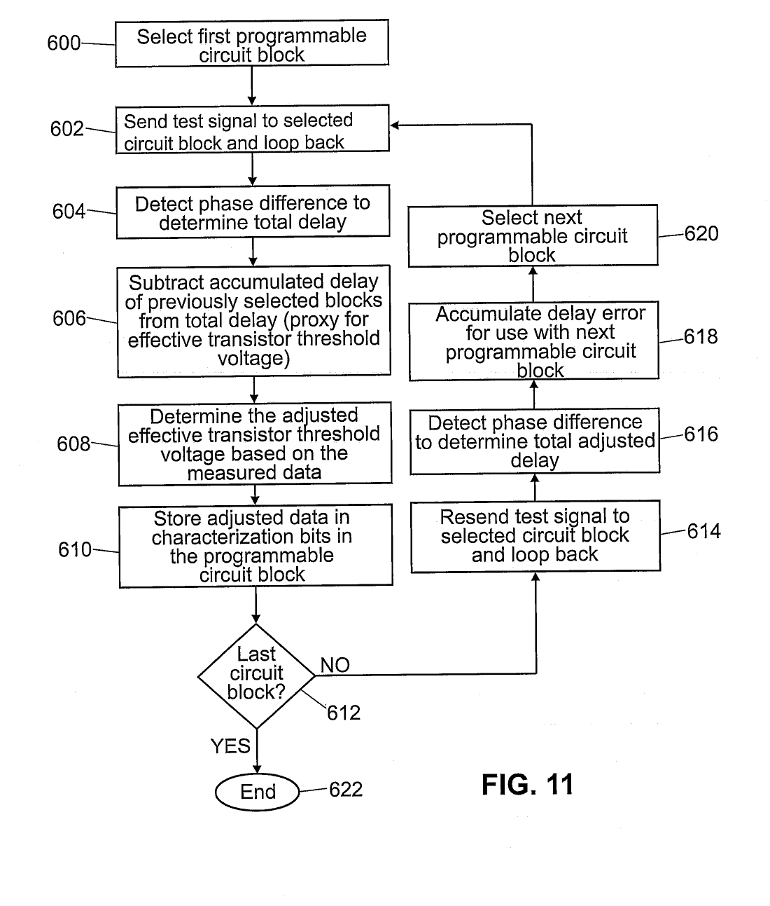

FIG. 11 shows a fourth illustrative method of implementing an FPGA in accordance with the present invention. Step 600 is to select the first programmable circuit block in the characterization sequence and then proceed to step 602. Step 602 sends a test signal from characterizer circuit 112 through the selected programmable circuit block 114 then loops it back to characterizer circuit 112. Step 602 then proceeds to step 604. Step 604 detects the phase difference between the outgoing and returning test signal to determine the total propagation delay of the test path and then proceeds to step 606. Step 606 subtracts the accumulated delay from previously selected blocks, if any, to determine the measured delay of the selected programmable circuit block 114 which is a proxy for the measured ETTV value and then proceeds to step 608. Step 608 determines the adjusted ETTV value for the selected block and then proceeds to step 610. Step 610 stores the adjusted ETTV value into the selected block's characterization bits and then proceeds to step 612. Step 612 makes a determination as to whether the currently selected programmable circuit block 114 is the last block in the characterization sequence. If step 612 determines the selected programmable circuit block 114 is the last block, then step 612 proceeds to step 622, otherwise step 612 proceeds to step 614. Step 622 is the end of the process.

Step 614 sends another test signal from characterizer circuit 112 through the selected programmable circuit block 114 then loops it back to characterizer circuit 112. Step 614 then proceeds to step 616. Step 616 detects the phase difference to determine the total adjusted delay and proceeds to step 618. Step 618 accumulates the correct delay for use with the next selected programmable circuit block 114 and then proceeds to step 620. Step 620 selects the next programmable circuit block 114 and then proceeds back to step 602. The method cycles through steps 602, 604, 606, 608, 610, 612, 614, 616, 618 and 620 for each programmable circuit block 114 in the characterization sequence until step 612 determines the last programmable circuit block 114 has been characterized and then exits the loop by proceeding to step 622.

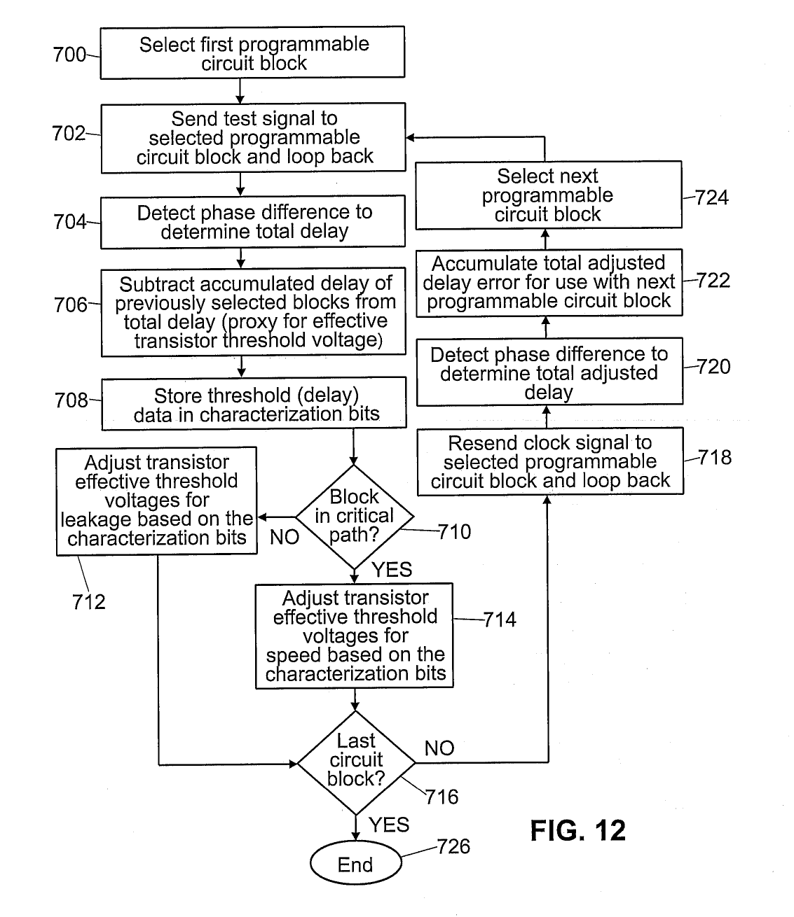

FIG. 12 shows a fifth illustrative method of implementing an FPGA in accordance with the present invention. Step 700 is to select the first programmable circuit block in the characterization sequence and then proceed to step 702. Step 702 sends a test signal from characterizer circuit 112 through the selected programmable circuit block 114 then loops it back to characterizer circuit 112. Step 702 then proceeds to step 704. Step 704 detects the phase difference between the outgoing and returning test signal to determine the total propagation delay of the test path and then proceeds to step 706. Step 706 subtracts the accumulated delay from previously selected blocks, if any, to determine the measured delay of the selected programmable circuit block 114 which is a proxy for the measured ETTV value and then proceeds to step 708. Step 708 determines the adjusted ETTV value and stores it into the configuration bits and then proceeds to step 710. Step 710 makes a determination as to whether the currently selected programmable circuit block 114 is in a critical path of the end user's design. If step 710 determines the selected programmable circuit block 114 is in the critical path, then step 710 proceeds to step 714, otherwise step 710 proceeds to step 712.

Step 712 makes a low-leakage adjustment to the adjusted ETTV value in the configuration bits and then proceeds to step 716. Step 714 does not make a low-leakage adjustment to the adjusted ETTV value in the configuration bits and proceeds to step 716.

Step 716 makes a determination as to whether the currently selected programmable circuit block 114 is the last block in the characterization sequence. If step 716 determines the selected programmable circuit block 114 is the last block, then step 716 proceeds to step 726, otherwise step 716 proceeds to step 718. Step 726 is the end of the process.

Step 718 sends another test signal from characterizer circuit 112 through the selected programmable circuit block 114 then loops it back to characterizer circuit 112. Step 718 then proceeds to step 720. Step 720 detects the phase difference to determine the total adjusted delay and proceeds to step 722. Step 722 accumulates the correct delay for use with the next selected programmable circuit block 114 and proceeds to step 724. Step 724 selects the next programmable circuit block 114 and proceeds back to step 702. The method cycles through steps 702, 704, 706, 708, 710, 712, 714, 716, 718, 720, 722, and 724 for each programmable circuit block 114 in the characterization sequence until step 716 determines the last programmable circuit block 114 has been characterized and then exits the loop by proceeding to step 726.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method for controlling transistor threshold voltages in a field programmable gate array integrated circuit device with a plurality of programmable circuit blocks, the method comprising:
selecting a target effective transistor threshold voltage;
measuring an effective transistor threshold voltage of each programmable circuit block; and
adjusting the effective transistor threshold voltage of each programmable circuit block based on the difference between the measured effective transistor threshold voltage and the target effective transistor threshold voltage.

2. The method of claim 1, wherein:
adjusting the effective transistor threshold voltage of a selected programmable circuit block includes setting at least one configuration bit coupled to the selected programmable circuit block.

3. The method of claim 2, wherein:
the at least one configuration bit coupled to a selected programmable circuit block controls the application of a body-bias voltage to at least one transistor inside the selected programmable circuit block.

4. The method of claim 1, wherein:
adjusting the effective transistor threshold voltage of a selected programmable circuit block includes selecting a body-bias voltage applied to at least one transistor inside the selected programmable circuit block.

5. The method of claim 1, wherein:
the target effective transistor threshold voltage is substantially equivalent to a mean effective transistor threshold voltage for a semiconductor process by which the field programmable gate array integrated circuit device is made.

6. The method of claim 1, wherein:
the target effective transistor threshold voltage is substantially higher than a mean effective transistor threshold voltage for a semiconductor process by which the field programmable gate array integrated circuit device is made.

7. The method of claim 1, wherein:
the target effective transistor threshold voltage is substantially lower than a mean effective transistor threshold voltage for a semiconductor process by which the field programmable gate array integrated circuit device is made.

8. The method of claim 1, wherein:
measuring the effective transistor threshold voltage of a selected programmable block includes measuring at least one characteristic of at least one individual transistor inside the selected programmable circuit block.

9. The method of claim 1, wherein:
measuring the effective transistor threshold voltage of a selected programmable circuit block includes measuring a propagation delay through a signal path inside the selected programmable circuit block.

10. A method for controlling transistor threshold voltages in a field programmable gate array integrated circuit device with a plurality of programmable circuit blocks disposed in an array of substantially contiguous rows and columns, the programmable circuit blocks to be characterized in a characterization sequence and adjusted in an adjustment sequence, the method comprising:
selecting a target effective transistor threshold voltage;
performing a characterization step, the characterization step including:
selecting a programmable circuit block in the characterization sequence,
measuring an effective transistor threshold voltage for the selected programmable circuit block,
storing the effective transistor threshold voltage for the selected programmable block, and
accumulating a delay error term for the next programmable circuit block in the sequence;
repeating the characterization step for all remaining programmable circuit blocks in the characterization sequence;
performing an adjustment step, the adjustment step including:
selecting a programmable circuit block in the adjustment sequence,
reading the effective transistor threshold voltage for the selected programmable circuit block from the memory,
determining the adjusted effective transistor threshold voltage of the selected programmable circuit block based on the difference between the measured effective transistor threshold of the programmable circuit block and the target effective transistor threshold voltage, and
applying the adjusted effective transistor threshold voltage to the selected programmable circuit block; and
repeating the adjustment step for all remaining programmable circuit blocks in the adjustment sequence.

11. The method of claim 10, wherein measuring the effective transistor threshold voltage for the selected programmable circuit block in the characterization sequence further comprises:
sending a test signal from a characterizer circuit to the selected programmable circuit block in the characterization sequence, through a test path inside the selected programmable circuit block, and back to the characterizer circuit;
measuring a total delay time of the test signal; and
subtracting the delay error term from the total delay time of the test signal.

12. The method of claim 11, wherein:
the characterizer circuit is internal to the field programmable gate array integrated circuit device.

13. The method of claim 11, wherein:
the characterizer circuit is external to the field programmable gate array integrated circuit device.

14. The method of claim 10, wherein:
applying the adjusted effective transistor threshold voltage to the selected programmable circuit block in the adjustment sequence includes setting at least one configuration bit coupled to the selected programmable circuit block in the adjustment sequence.

15. The method of claim 14, wherein:
the at least one configuration bit coupled to the selected programmable circuit block in the adjustment sequence controls the application of a body-bias voltage to at least one transistor inside the selected programmable circuit block in the adjustment sequence.

16. The method of claim 10, wherein:
applying the adjusted effective transistor threshold voltage of to the selected programmable circuit block in the adjustment sequence includes selecting a body-bias voltage applied to at least one transistor inside the selected programmable circuit block in the adjustment sequence.

17. The method of claim 10, wherein the adjustment step further comprises the steps of:
selecting at least one critical path;
further adjusting the adjusted effective transistor threshold voltage of the selected programmable circuit block upward if the selected programmable circuit block is not on a selected critical path.

18. A method for controlling transistor threshold voltages in a field programmable gate array integrated circuit device with a plurality of programmable circuit blocks disposed in an array of substantially contiguous rows and columns, the programmable circuit blocks to be characterized in a sequence, the method comprising:
selecting a target effective transistor threshold voltage;
performing a characterization step, the characterization step including:
selecting a programmable circuit block in the sequence,
measuring an effective transistor threshold voltage for the selected programmable circuit block,
adjusting the effective transistor threshold voltage of the selected programmable circuit block based on the difference between the measured effective transistor threshold voltage and the target effective transistor threshold voltage, and
accumulating a delay error term for the next programmable circuit block in the sequence; and
repeating the characterization step for all remaining programmable circuit blocks in the sequence.

19. The method of claim 18, wherein measuring the effective transistor threshold voltage for the selected programmable circuit block further comprises:
sending a test signal from a characterizer circuit to the selected programmable circuit block, through a test path inside the selected programmable circuit block, and back to the characterizer circuit;
measuring a total delay time of the test signal; and
subtracting a delay error term from the total delay time of the test signal.

20. The method of claim 19, wherein:
the characterizer circuit is internal to the field programmable gate array integrated circuit device.

21. The method of claim 19, wherein:
the characterizer circuit is external to the field programmable gate array integrated circuit device.

22. The method of claim 18, wherein:
adjusting the effective transistor threshold voltage of a selected programmable circuit block includes setting at least one configuration bit coupled to the selected programmable circuit block.

23. The method of claim 22, wherein:
the at least one configuration bit coupled to the selected programmable circuit block controls the application of a body-bias voltage to at least one transistor inside the selected programmable circuit block.

24. The method of claim 18, wherein:
adjusting the effective transistor threshold voltage of a selected programmable circuit block includes selecting a body-bias voltage applied to at least one transistor inside the selected programmable circuit block.

25. The method of claim 22, further comprising the steps of:
selecting at least one critical path;
adjusting the effective transistor threshold voltage of the selected programmable circuit block upward if the selected programmable circuit block is not on a selected critical path.
